(19) United States
(12) Patent Application Publication
(10) Pub. No.: US 2024/0288739 A1
(43) Pub. Date: Aug. 29, 2024

(54) ELECTRONIC DEVICE

(71) Applicant: Japan Display Inc., Tokyo (JP)

(72) Inventors: Hajime WATAKABE, Tokyo (JP); Masashi TSUBUKU, Tokyo (JP); Toshinari SASAKI, Tokyo (JP); Takaya TAMARU, Tokyo (JP); Marina MOCHIZUKI, Tokyo (JP); Ryo ONODERA, Tokyo (JP)

(21) Appl. No.: 18/433,729

(22) Filed: Feb. 6, 2024

(30) Foreign Application Priority Data
Feb. 27, 2023 (JP) 2023-028209

(51) Int. Cl. G02F 1/1362; G02F 1/1368; H01L 27/12

(52) U.S. Cl. CPC G02F 1/136295; G02F 1/13685; H01L 27/124; H01L 27/1255; H01L 27/1274; H01L 27/1225

(57) ABSTRACT

An electronic device comprises a first stacked structure including a first oxide semiconductor layer having a polycrystalline structure, a first insulating layer on the first oxide semiconductor layer, and a first conductive layer overlapping the first oxide semiconductor layer via the first insulating layer; and a second stacked structure including a second oxide semiconductor layer composed of the same layer as the first oxide semiconductor layer, the first insulating layer on the second oxide semiconductor layer, and a second conductive layer overlapping the second oxide semiconductor layer via the first insulating layer and composed of the same layer as the first conductive layer. A portion of the first oxide semiconductor layer not overlapping the first conductive layer contains an impurity element, and the second oxide semiconductor layer does not contain the impurity element.

### CROSS REFERENCE TO RELATED APPLICATIONS

This application claims the benefit of priority to Japanese Patent Application No. 2023-028209, filed on Feb. 27, 2023, the entire contents of which are incorporated herein by reference.

### FIELD

An embodiment of the present invention relates to an electronic device and a method for manufacturing the same. In particular, an embodiment of the present invention relates to an electronic device including a semiconductor device using an oxide semiconductor and a method for manufacturing the same.

### BACKGROUND

A semiconductor device (for example, a thin film transistor) using an oxide semiconductor containing metal oxide as an active layer has been developed in recent years in place of an inorganic semiconductor such as silicon (see, for example, Japanese laid-open patent publication No. 2021-141338, Japanese laid-open patent publication No. 2014-099601, Japanese laid-open patent publication No. 2021-153196, Japanese laid-open patent publication No. 2018-006730, Japanese laid-open patent publication No. 2016-184771, and Japanese laid-open patent publication No. 2021-108405). The semiconductor device using an oxide semiconductor can be formed in a simple-structure and low-temperature process, similar to a semiconductor device using amorphous silicon as an active layer. It is known that the oxide semiconductor using an oxide semiconductor as an active layer has higher field-effect mobility than the semiconductor device using amorphous silicon as an active layer.

### SUMMARY

An electronic device in one embodiment of the invention comprises a first stacked structure including a first oxide semiconductor layer having a polycrystalline structure, a first insulating layer on the first oxide semiconductor layer, and a first conductive layer overlapping the first oxide semiconductor layer via the first insulating layer; and a second stacked structure including a second oxide semiconductor layer composed of the same layer as the first oxide semiconductor layer, the first insulating layer on the second oxide semiconductor layer, and a second conductive layer overlapping the second oxide semiconductor layer via the first insulating layer and composed of the same layer as the first conductive layer. A portion of the first oxide semiconductor layer not overlapping the first conductive layer contains an impurity element, and the second oxide semiconductor layer does not contain the impurity element.

An electronic device in one embodiment of the invention comprises a first stacked structure including a first oxide semiconductor layer having a polycrystalline structure, a first insulating layer on the first oxide semiconductor layer, and a first conductive layer overlapping the first oxide semiconductor layer via the first insulating layer; and a second stacked structure including a second oxide semiconductor layer composed of the same layer as the first oxide semiconductor layer, the first insulating layer on the second oxide semiconductor layer, and a second conductive layer overlapping the second oxide semiconductor layer via the first insulating layer and composed of the same layer as the first conductive layer. The first oxide semiconductor layer includes a first portion overlapping the first conductive layer and a second portion not overlapping the first conductive layer, the second oxide semiconductor layer includes a third portion overlapping the second conductive layer and a fourth portion not overlapping the second conductive layer, the second portion, the third portion and the fourth portion contain an impurity element, and the first portion does not contain the impurity element.

A method for manufacturing the electronic device in one embodiment of the invention comprises forming a first oxide semiconductor layer and a second oxide semiconductor layer having a polycrystalline structure on an insulating surface, forming a first insulating layer on the first oxide semiconductor layer and the second oxide semiconductor layer, forming a first conductive layer overlapping a portion of the first oxide semiconductor layer and a second conductive layer overlapping at least a portion of the second oxide semiconductor layer on the first insulating layer, forming a resist mask covering the second oxide semiconductor layer and the second conductive layer, performing an ion implantation from above the first conductive layer and the resist mask to add impurity elements to a portion of the first oxide semiconductor layer, and after removing the resist mask, forming an insulating layer containing hydrogen on the first conductive layer and the second conductive layer.

A method for manufacturing the electronic device in one embodiment of the invention comprises forming a first oxide semiconductor layer and a second oxide semiconductor layer having a polycrystalline structure on an insulating surface, forming a first insulating layer on the first oxide semiconductor layer and the second oxide semiconductor layer, forming a resist mask covering a portion of the first oxide semiconductor layer on the first insulating layer, performing an ion implantation from above the resist mask to add impurity elements to a portion of the first oxide semiconductor layer and the second oxide semiconductor layer, after removing the resist mask, forming a first conductive layer overlapping a portion of the first oxide semiconductor layer and a second conductive layer overlapping at least a portion of the second oxide semiconductor layer on the first insulating layer, and forming an insulating layer containing hydrogen on the first conductive layer and the second conductive layer.

A method for manufacturing the electronic device in one embodiment of the invention comprises forming a first oxide semiconductor layer and a second oxide semiconductor layer having a polycrystalline structure on an insulating surface, forming a first insulating layer on the first oxide semiconductor layer and the second oxide semiconductor layer, forming a resist mask covering a portion of the first oxide semiconductor layer on the first insulating layer, performing an ion implantation from above the resist mask to add impurity elements to the second oxide semiconductor, after removing the resist mask, forming a first conductive layer overlapping a portion of the first oxide semiconductor layer and a second conductive layer overlapping at least a portion of the second oxide semiconductor layer on the first insulating layer, performing an ion implantation from above the first conductive layer and the second conductive layer to add impurity elements to a portion of the first oxide semiconductor and a portion of the second oxide semiconductor, and forming an insulating layer containing hydrogen on the first conductive layer and the second conductive layer.

### BRIEF DESCRIPTION OF THE DRAWINGS

FIG. 1 is a plan view showing a configuration of a display device according to an embodiment of the present invention.

FIG. 2 is a diagram showing a configuration of a pixel circuit in a display device according to an embodiment of the present invention.

FIG. 3 is a plan view showing a configuration of a touch sensor circuit in a display device according to an embodiment of the present invention.

FIG. 4 is a cross-sectional view showing a configuration of a pixel in a display device according to an embodiment of the present invention.

FIG. 5 is a cross-sectional view showing a configuration of a semiconductor device used in a display device according to an embodiment of the present invention.

FIG. 6 is a plan view showing a configuration of a semiconductor device used in a display device according to an embodiment of the present invention.

FIG. 7A is a schematic view for explaining a bonding state of Poly-OS contained in a conductive portion of an oxide semiconductor layer.

FIG. 7B is a schematic view for explaining a bonding state of Poly-OS contained in a conductive portion of an oxide semiconductor layer.

FIG. 7C is a schematic view for explaining a bonding state of Poly-OS contained in a conductive portion of an oxide semiconductor layer.

FIG. 8 is a band diagram for explaining a band structure of a conductive portion of an oxide semiconductor layer.

FIG. 9 is a sequence diagram showing a method for manufacturing a semiconductor device used in a display device according to an embodiment of the present invention.

FIG. 10 is a cross-sectional view showing a method for manufacturing a semiconductor device used in a display device according to an embodiment of the present invention.

FIG. 11 is a cross-sectional view showing a method for manufacturing a semiconductor device used in a display device according to an embodiment of the present invention.

FIG. 12 is a cross-sectional view showing a method for manufacturing a semiconductor device used in a display device according to an embodiment of the present invention.

FIG. 13 is a cross-sectional view showing a method for manufacturing a semiconductor device used in a display device according to an embodiment of the present invention.

FIG. 14 is a cross-sectional view showing a method for manufacturing a semiconductor device used in a display device according to an embodiment of the present invention.

FIG. 15 is a cross-sectional view showing a method for manufacturing a semiconductor device used in a display device according to an embodiment of the present invention.

FIG. 16 is a cross-sectional view showing a method for manufacturing a semiconductor device used in a display device according to an embodiment of the present invention.

FIG. 17 is a cross-sectional view showing a method for manufacturing a semiconductor device used in a display device according to an embodiment of the present invention.

FIG. 18 is a cross-sectional view showing a method for manufacturing a semiconductor device used in a display device according to an embodiment of the present invention.

FIG. 19 is a cross-sectional view showing a method for manufacturing a display device according to an embodiment of the present invention.

FIG. 20 is a sequence diagram showing a method for manufacturing a display device according to an embodiment of the present invention.

FIG. 21 is a cross-sectional view showing a method for manufacturing a display device according to an embodiment of the present invention.

FIG. 22 is a cross-sectional view showing a method for manufacturing a display device according to an embodiment of the present invention.

FIG. 23 is a cross-sectional view showing a method for manufacturing a display device according to an embodiment of the present invention.

FIG. 24 is a cross-sectional view showing a method for manufacturing a display device according to an embodiment of the present invention.

FIG. 25 is a cross-sectional view showing a method for manufacturing a display device according to an embodiment of the present invention.

FIG. 26 is a cross-sectional view showing a method for manufacturing a display device according to an embodiment of the present invention.

FIG. 27 is a cross-sectional view showing a method for manufacturing a display device according to an embodiment of the present invention.

FIG. 28 is a cross-sectional view showing a method for manufacturing a display device according to an embodiment of the present invention.

FIG. 29 is a cross-sectional view showing a method for manufacturing a display device according to an embodiment of the present invention.

FIG. 30 is a diagram showing a structure of a pixel in a display device according to an embodiment of the present invention.

FIG. 31 is a cross-sectional view showing a configuration of a semiconductor device used in a display device according to an embodiment of the present invention.

FIG. 32 is a sequence diagram showing a method for manufacturing a semiconductor device used in a display device according to an embodiment of the present invention.

FIG. 33 is a cross-sectional view showing a method for manufacturing a semiconductor device used in a display device according to an embodiment of the present invention.

FIG. 34 is a cross-sectional view showing a method for manufacturing a semiconductor device used in a display device according to an embodiment of the present invention.

FIG. 35 is a cross-sectional view showing a method for manufacturing a semiconductor device used in a display device according to an embodiment of the present invention.

FIG. 36 is a sequence diagram showing a method for manufacturing a semiconductor device used in a display device according to an embodiment of the present invention.

FIG. 37 is a sequence diagram showing a method for manufacturing a semiconductor device used in a display device according to an embodiment of the present invention.

FIG. 38 is a configuration of a pixel circuit in a display device of one embodiment of the present invention.

FIG. 39 is a structure of a pixel in a display device of one embodiment of the present invention.

### DESCRIPTION OF EMBODIMENTS

Since an oxide semiconductor has light transmittance, it can be used as a wiring material with low resistance, which is very advantageous in improving the transmittance of an array substrate (a substrate in which a plurality of semiconductor devices is arranged in an array). However, it is difficult to sufficiently reduce resistivity of a conventional oxide semiconductor, and it is difficult to use it as a wiring material.

An object of an embodiment of the present invention is to provide an electronic device using an oxide semiconductor as a wiring material.

Hereinafter, each embodiment of the present invention will be described with reference to the drawings. The following invention is merely an example. A configuration that can be easily conceived by a person skilled in the art by appropriately changing the configuration of the embodiment while keeping the gist of the invention is naturally included in the scope of the present invention. In order to make the description clearer, the drawings may schematically show the width, thickness, shape, and the like of each part in comparison with an actual embodiment. However, the illustrated shapes are merely examples, and do not limit the interpretation of the present invention. In the present specification and the drawings, the same reference signs are given to elements similar to those described above with respect to the above-described drawings, and detailed description thereof may be omitted as appropriate.

In each embodiment, a direction from a substrate to an oxide semiconductor layer is referred to as “on” or “above”. Conversely, a direction from the oxide semiconductor layer to the substrate is referred to as “under” or “below”. In this way, for convenience of explanation, the phrase “above” or “below” is used to describe, but for example, the upper and lower relations between the substrate and the oxide semiconductor layer may be arranged so as to be opposite to those shown in the drawings. In the following explanation, for example, the expression “an oxide semiconductor layer on a substrate” merely describes the upper and lower relationship between the substrate and the oxide semiconductor layer as described above, and another member may be arranged between the substrate and the oxide semiconductor layer. The term “upper or lower” refer to the stacking order in a structure in which a plurality of layers is stacked, and when expressed as “a pixel electrode above a transistor” may be a positional relationship in which the transistor and the pixel electrode do not overlap each other in a plan view. On the other hand, the expression “a pixel electrode vertically above a transistor” means a positional relationship in which the transistor and the pixel electrode overlap each other in a plan view.

In each embodiment, a plurality of elements formed by performing processing such as etching on one film may be described as elements having different functions or roles. These elements are composed of the same layer structure and the same material and are described as elements composed of the same layer.

The terms “identical,” “match,” and the like do not refer to exactly the same or exact matches only, but also include ranges that can be considered substantially the same or identical, in each embodiment. For example, the case where certain numerical values are the same includes the case where the numerical values are different within a range of ±5% (preferably ±3%) in addition to the case where the numerical values are completely the same.

The expression “no impurity element is included” includes not only the case where no impurity element is included, but also the case where the concentration of the impurity element is lower than the detection lower limit of an analyzer, in each embodiment. Normally, impurity elements such as argon (Ar), phosphorus (P) or boron (B) are not included in the oxide semiconductor unless intentionally added. However, the impurity element may be unintentionally mixed during the formation of another film. Even in such a case, if the concentration is lower than the detection lower limit of the analyzer to be used, it may be regarded as substantially free of impurity elements.

An “electronic device” refers to a device that includes a semiconductor element, such as a transistor, and performs electronic operations, in this specification. For example, a display device and a semiconductor-integrated device are included in the electronic device of this specification. “Display device” refers to a device that displays an image using an electro-optic layer. The “Electro-optic layer” may include a liquid crystal layer, an electroluminescent (EL) layer, an electrochromic (EC) layer, an electrophoretic layer, unless there is a technical inconsistency. In addition, the term display device includes not only a display panel including the electro-optic layer, but also a device with other optical members (for example, a polarizing member or a backlight) attached to the display panel. The “semiconductor-integrated device” is a device including a circuit in which semiconductor devices are integrated. For example, a CPU (Central Calculation Processing Device), a storage device (Memory), and an image sensor may be included in the semiconductor-integrated device.

In each embodiment, the expressions “a includes A, B, or C,” “a includes any of A, B, or C,” and “a includes one selected from a group consisting of A, B, and C” do not exclude the case where a includes a plurality of combinations of A to C unless otherwise indicated. Furthermore, these expressions do not exclude the case where a includes other elements.

### First Embodiment

### [Configuration of Display Device]

A display device 100 according to an embodiment of the present invention will be described. The display device 100 of the present embodiment is a liquid crystal display device including a liquid crystal layer as an electro-optic layer. The display device 100 is an example of an electronic device to which the present invention is applied.

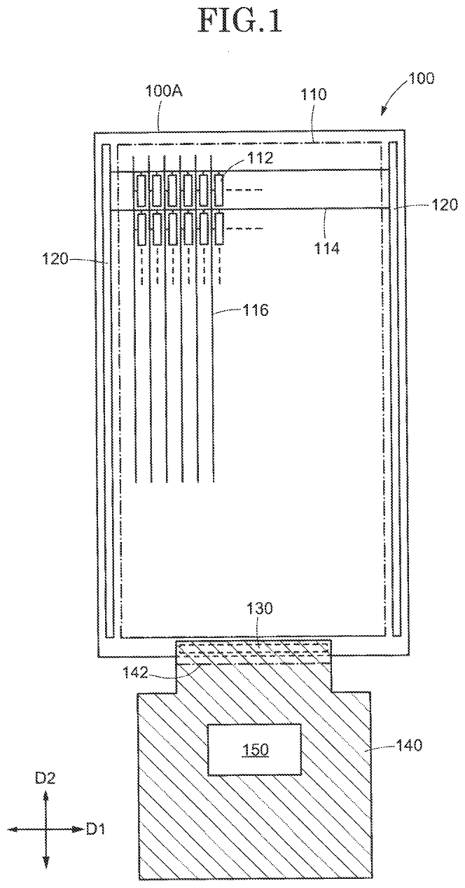

FIG. 1 is a plan view showing a configuration of the display device 100 according to an embodiment of the present invention. A display portion 110, a scanning side drive portion 120, and a terminal portion 130 are arranged on a front surface side of a circuit substrate 100A of the display device 100, as shown in FIG. 1.

The circuit substrate 100A is a substrate in which a plurality of semiconductor devices formed using an oxide semiconductor is arranged on a support substrate having light transmittance. Although an example in which a thin film transistor is arranged as a semiconductor device is shown in the present embodiment, the present invention is not limited to this example, and other semiconductor devices may be arranged as long as an element functions as a switching element. The circuit substrate 100A may also be referred to as an active matrix substrate. A substrate having light transmittance can be used as the support substrate constituting the circuit substrate 100A. For example, a glass substrate or a substrate having flexibility is preferably used as the support substrate.

The display portion 110 is a portion for controlling a plurality of pixels 112 for displaying an image. Specifically, the display portion 110 includes a plurality of scanning signal lines 114 extending in a direction D1 (row direction) and a plurality of video signal lines 116 extending in a direction D2 (column direction), and the pixel 112 including a thin film transistor corresponding to each of intersections of the plurality of scanning signal lines 114 and the plurality of video signal lines 116. The individual pixels 112 are sub-pixels corresponding to any of the colors R (red), G (green), and B (blue), in the present embodiment. Therefore, in practice, a color is displayed in units of one pixel (main pixel) including three pixels 112 corresponding to each color of RGB.

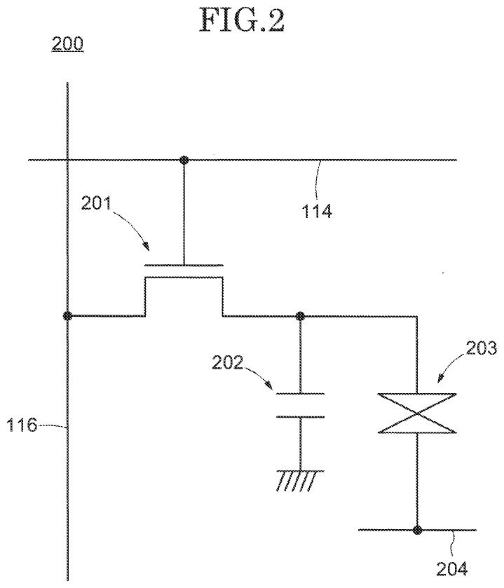

A pixel circuit 200 for controlling light emission of each pixel 112 will be described with reference to FIG. 2, in this case. Although a basic configuration using a single semiconductor device (thin film transistor) and a single storage capacitor will be described as an example for convenience of explanation, the configuration of the pixel circuit 200 is not limited to this example.

FIG. 2 is a diagram showing a configuration of the pixel circuit 200 in the display device 100 according to an embodiment of the present invention. The pixel circuit 200 includes a select transistor 201, a capacitive element 202, and a liquid crystal element 203, as shown in FIG. 2. The select transistor 201 is a thin film transistor including a channel portion composed of the oxide semiconductor layer, as will be described later.

A gate of the select transistor 201 is connected to the scanning signal line 114. A source of the select transistor 201 is connected to the video signal line 116. A gradation signal determining the amount of light transmitted through the liquid crystal element 203 is supplied to the video signal line 116. A scanning signal for selecting a pixel to which the gradation signal is written is supplied to the scanning signal line 114. A drain of the select transistor 201 is connected to the capacitive element 202 and the liquid crystal element 203. The source and the drain of the select transistor 201 may be switched depending on the magnitude of the relationship between the voltage applied to the video signal line 116 and the voltage stored in the capacitive element 202.

The capacitive element 202 is a capacitor that holds the voltage input from the video signal line 116 via the select transistor 201. One electrode of the capacitive element 202 is connected to the drain of the select transistor 201 and the other electrode is fixed at the ground potential. However, the present invention is not limited to this example, and the other electrode may be fixed at other potentials.

The liquid crystal element 203 is an electro-optic element having a configuration in which a liquid crystal layer is arranged between a pair of electrodes. Although a specific configuration will be described later, the liquid crystal element 203 of the present embodiment includes a pixel electrode connected to the drain of the select transistor 201 and a common electrode connected to a common wiring 204, and an orientation of liquid crystal molecules is controlled by an electric field formed between the pixel electrode and the common electrode.

The above-described pixel circuit 200 is arranged in each pixel 112 of the display device 100. In other words, it can be said that the display portion 110 shown in FIG. 1 is constituted by an aggregate of the pixel circuit 200.

The description is returned to FIG. 1. The scanning side drive portion 120 is coupled to the scanning signal line 114 and transmits a scanning signal to the scanning signal line 114. Specifically, the scanning signal is applied to the gate of the select transistor 201 shown in FIG. 2 and used for switching control of the select transistor 201. A drive circuit constituting the scanning side drive portion 120 is also formed using a thin film transistor like the pixel circuit 200 included in the plurality of pixels 112, in the present embodiment, but may be replaced with an IC chip or the like. In addition, although two scanning side drive portions 120 are arranged on the circuit substrate 100A with the display portion 110 interposed therebetween, only one of the scanning side drive portions 120 may be arranged, in the present embodiment.

The terminal portion 130 is a portion for electrically connecting various wirings arranged in the circuit substrate 100A to a flexible printed circuit substrate 140. Specifically, the terminal portion 130 is an assembly of terminals connected to the plurality of video signal lines 116, a wiring (not shown) for supplying a control signal to the scanning side drive portion 120, and the common wiring 204 (see FIG. 2). The terminal portion 130 is arranged outside the display portion 110. The video signal and control signal supplied from the outside are respectively supplied to the display portion 110 and the scanning side drive portion 120 via the terminal portion 130.

The flexible printed circuit substrate 140 is connected to the terminal portion 130. The flexible printed circuit substrate 140 is an interface substrate for connecting the circuit substrate 100A and an external control circuit (not shown). A display control circuit 150 is mounted on the flexible printed circuit substrate 140 in the present embodiment. The display control circuit 150 is a signal processing circuit that executes signal processing of a video signal to be supplied to the display portion 110 and various control signals to be supplied to the scanning side drive portion 120. The display control circuit 150 is mounted on the flexible printed circuit substrate 140 in the form of an IC chip in the present embodiment.

Since the flexible printed circuit substrate 140 is a circuit substrate in which a wiring is printed on a flexible substrate composed of resin material, it can be folded. The flexible printed circuit substrate 140 may be bent by a folding line 142 indicated by a dash-dot line so that the flexible printed circuit substrate 140 and a back surface side of the circuit substrate 100A (the side on which the display portion 110 or the like is not formed) overlap each other, in the present embodiment.

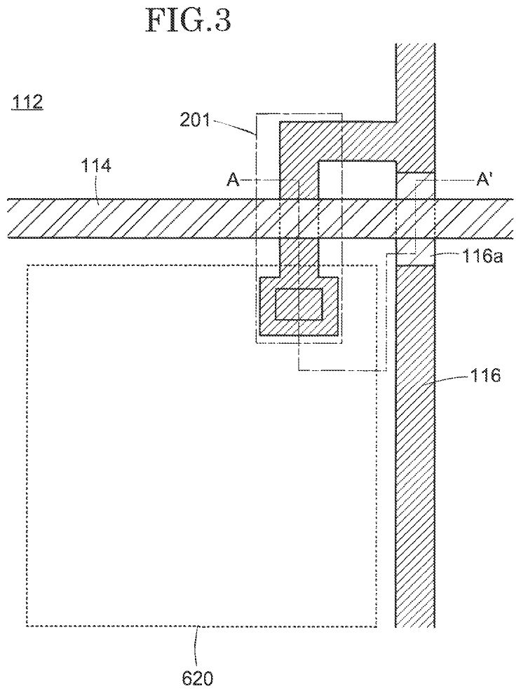

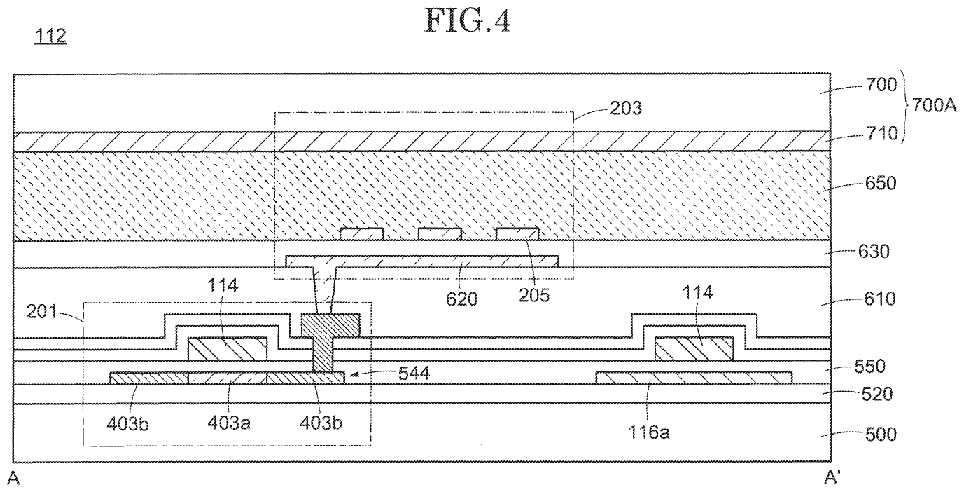

FIG. 3 is a plan view showing a structure of the pixel 112 in the display device 100 according to an embodiment of the present invention. FIG. 4 is a cross-sectional view showing a structure of the pixel 112 in the display device 100 according to an embodiment of the present invention. Specifically, FIG. 4 corresponds to a cross-sectional view obtained by cutting the pixel structure shown in FIG. 3 with A-A′. The capacitive element 202 and the liquid crystal element 203 are not illustrated in FIG. 3 for convenience of explanation.

The scanning signal line 114 and the video signal line 116 are arranged so as to cross each other, and the select transistor 201 is arranged corresponding to the intersection, as shown in FIG. 3 and FIG. 4. The scanning signal line 114 is arranged above an oxide semiconductor layer 544 functioning as the active layer via an insulating layer 550, in the select transistor 201. A portion of the scanning signal line 114 that intersects the oxide semiconductor layer 544 functions as a gate electrode. That is, a stacked structure composed of the oxide semiconductor layer 544, the insulating layer 550, and the scanning signal line 114 is included in the select transistor 201.

In addition, the scanning signal line 114 is arranged above a portion of the video signal line 116 (hereinafter referred to as an “intersection portion 116a”) via the insulating layer 550 at the portion where the scanning signal line 114 and the video signal line 116 intersect. That is, a stacked structure composed of the intersection portion 116a, the insulating layer 550, and the scanning signal line 114 is formed at the portion where the scanning signal line 114 and the video signal line 116 intersect.

The video signal line 116 in this case is composed of the same layer as a conductive portion 403b functioning as a source region or a drain region of the select transistor 201, in the present embodiment. Specifically, the oxide semiconductor layer 544 functioning as active layer of the select transistor 201 and the video signal line 116 are integrally formed. In other words, each of the plurality of pixels 112 is connected by the video signal line 116 composed of the same layer as the active layer of the select transistor 201.

The resistivity of the oxide semiconductor layer functioning as the active layer (specifically, the conductive portion 403b) of the select transistor 201 is lower than that of the conventional oxide semiconductor layer, in the present embodiment. Therefore, the oxide semiconductor layer can be used as the wiring (in the present embodiment, the video signal line 116), in the present embodiment. The reason why the oxide semiconductor of the present embodiment can be used as the wiring material will be described later.

In addition, the configuration of the intersection portion 116a of the video signal line 116 is different from the configuration of the other portions, in the present embodiment. Specifically, the video signal line 116 basically has the same configuration as that of the conductive portion 403b of the select transistor 201, whereas the impurity element contained in the conductive portion 403b is not contained in the intersection portion 116a. This point will be described later.

A specific structure of the pixel 112 will be described with reference to FIG. 4. The select transistor 201 is arranged above a substrate 500, as shown in FIG. 4. The substrate 500 is a substrate having light transmittance, and for example, a glass substrate or a resin substrate can be used. An insulating layer 520 is composed of a silicon oxide layer, a silicon nitride layer, or a stacked film of a silicon oxide layer and a silicon nitride layer. The insulating layer 520 prevents impurities and the like from entering from the substrate 500.

The select transistor 201 of the present embodiment includes the oxide semiconductor layer 544 composed of an oxide semiconductor with a polycrystalline structure. For example, a metal oxide containing two or more metals including indium (In) is used as the oxide semiconductor. Normally, the oxide semiconductor has light transmittance and is transparent to visible light. The oxide semiconductor layer 544 include a channel portion 403a and the conductive portion 403b. The channel portion 403a functions as a channel of the select transistor 201. The conductive portion 403b functions as the source or drain of the select transistor 201.

Although an example in which a thin film transistor having a top-gate structure is used as the select transistor 201 is shown in the present embodiment, a thin film transistor having a dual-gate structure including the gate electrode may be used below the oxide semiconductor layer 544. The gate electrode arranged below the oxide semiconductor layer 544 may block light from the substrate 500 side toward the channel portion 403a. Therefore, in the case where the select transistor 201 has the dual-gate structure, leakage current due to light irradiation can be suppressed, and an off-state current can be reduced. In addition, an on-state current is expected to be increased because the gate-voltage is applied to the channel portion 403a of the oxide semiconductor layer 544 from above and below.

The intersection portion 116a shown in FIG. 3 is formed of the same layer as the oxide semiconductor layer 544 constituting the select transistor 201. That is, the oxide semiconductor layer 544 and the intersection portion 116a are elements derived from the same oxide semiconductor layer in the present embodiment. Although the intersection portion 116a is formed at the same time as the oxide semiconductor layer 544, a method of reducing resistance is different from that of the conductive portion 403b. Specifically, the conductivity of the conductive portion 403b is imparted in the process of adding an impurity element to the oxide semiconductor layer 544, whereas the conductivity of the intersection portion 116a is imparted by a process such as hydrogenation without adding an impurity element. This will be described later together with the method for manufacturing the select transistor 201.

A planarization layer 610 composed of resin material is arranged above the scanning signal line 114. The planarization layer 610 serves to planarize unevenness on the substrate 500 caused by the formation of the select transistor 201. A pixel electrode 620 is arranged above the planarization layer 610. The pixel electrode 620 is composed of a transparent conductive film containing metal oxide such as ITO. The pixel electrode 620 is connected to the select transistor 201 via a contact hole arranged in the planarization layer 610.

An insulating layer 630 is arranged above the pixel electrode 620. The insulating layer 630 is composed of a silicon oxide layer, a silicon nitride layer, or a stacked structure thereof. A common electrode 205 is arranged above the insulating layer 630 so as to partially overlap the pixel electrode 620. The common electrode 205 is composed of a transparent conductive film containing metal oxide such as ITO, like the pixel electrode 620.

The common electrode 205 has a comb-like pattern shape, in the present embodiment. For example, the common electrode 205 has a pattern shape in which a plurality of linear electrodes extending in the direction D2 is connected to a linear electrode extending in the direction D1 in FIG. 1. Although three electrode patterns overlapping the pixel electrode 620 are illustrated in the example shown in FIG. 4, which correspond to cross-sections of the plurality of linear electrodes extending in the direction D2 and are electrically connected.

An FFS (Fringe Field Switching) method in which a fringe electric field is formed between the pixel electrode 620 and the common electrode 205 to align liquid crystal molecules in a liquid crystal layer 650 is used in the present embodiment. Since the FFS method is known as a driving method of a liquid crystal display device, the explanation thereof will be omitted. A predetermined voltage (for example, a ground voltage) is applied to the common electrode 205 when forming the fringe electric field. That is, the strength of the fringe field is controlled by the voltage applied to the pixel electrode 620. The common electrode 205 functions as an electrode for applying a voltage to the liquid crystal layer by being held at a constant voltage during a display period, as described above.

Although an example of using the FFS method in which the fringe electric field is formed between the pixel electrode 620 and the common electrode 205 as a display method has been described in the present embodiment, the present invention is not limited to this example. For example, an IPS (In-Plane Switching) method may be adopted as the display method. Both pixel electrode and common electrode may be configured in a comb-like pattern shape, and comb-shaped portions of the pixel electrode and the common electrode may be arranged so as to face each other, in this case. In the case of the IPS method, a lateral electric field is formed by the pixel electrode and the common electrode facing each other in a transverse direction, and orientation control of the liquid crystal molecules is performed by the lateral electric field.

A substrate 700 and a color filter 710 are arranged above the pixel electrode 620 and the common electrode 205 via the liquid crystal layer 650. The substrate 700 and the color filter 710 are collectively referred to as a counter substrate 700A in the present embodiment. The liquid crystal layer 650 is arranged between the circuit substrate 100A and the counter substrate 700A, which are bonded together by a sealing material (not shown). Although not shown in FIG. 4, an alignment film is arranged on the surfaces of the circuit substrate 100A and the counter substrate 700A in contact with the liquid crystal layer 650. Although only the color filter 710 is illustrated on the substrate 700 in the present embodiment, a light-shielding film (a so-called black matrix) may be arranged as needed.

As described above, in the present embodiment, the semiconductor device (the select transistor 201) having the oxide semiconductor layer 544 as the active layer is arranged in each pixel 112, and the video signal line 116 (including the intersection portion 116a) is composed of the oxide semiconductor layer composed of the same layer as the active layer. The resistivity of the video signal line 116 of the present embodiment at the part overlapping the scanning signal line 114 is sufficiently low to function as the wiring, in this case. Therefore, in the case where the signal is supplied to the video signal line 116, a signal delay or the like caused by resistance components can be suppressed.

The oxide semiconductor layer 544 used in the select transistor 201 of the present embodiment has a polycrystalline structure and is excellent in crystallinity. In addition, the conductive portion 403b having conductivity imparted to the oxide semiconductor layer 544 of the present embodiment has a feature that the resistance is significantly lower than that of the conventional one. Specifically, the sheet resistance of the conductive portion 403b is 1000 Ω/sq. or less (preferably 500 Ω/sq. or less, more preferably 250 Ω/sq. or less), and can be sufficiently used as the wiring. The display device 100 of the present embodiment focuses on the physical properties of the oxide semiconductor layer 544, and the video signal line 116 is composed of the same layer as the oxide semiconductor layer 544.

According to the present embodiment, the video signal line 116 can be composed of a light-transmitting material (specifically, the oxide semiconductor layer 544 made of metal oxide). Moreover, since the video signal line 116 can be formed simultaneously with the oxide semiconductor layer 544 used for the select transistor 201, the aperture ratio of the display portion of the display device 100 can be improved with a simple structure.

The structure of the display portion 110 described above is realized by reducing the resistivity of the oxide semiconductor layer to a level that can be used as a wiring. Specifically, it is realized by reducing the resistance of the conductive portion 403b of the select transistor 201 which is the semiconductor device using the oxide semiconductor. Therefore, the configuration and the method for manufacturing the semiconductor device (the select transistor 201 in FIG. 4) used in the present embodiment will be described below.

### [Configuration of Semiconductor Device]

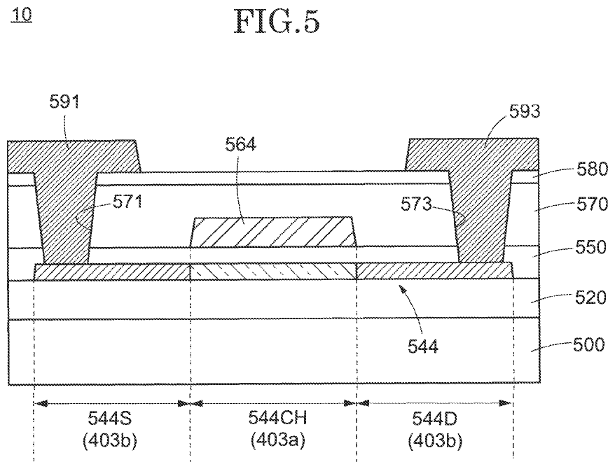

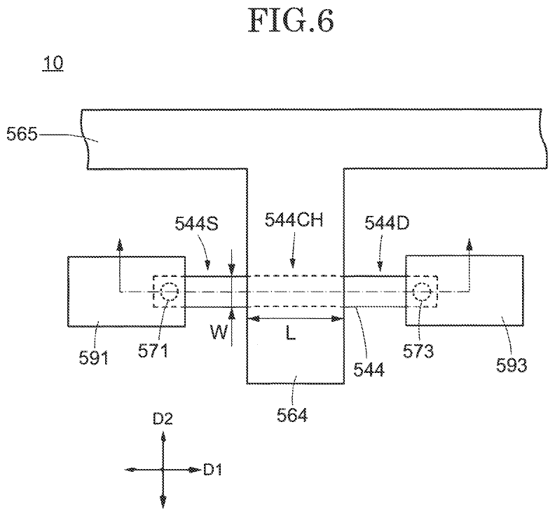

FIG. 5 is a cross-sectional view showing a configuration of a semiconductor device 10 used in the display device 100 according to an embodiment of the present invention. FIG. 6 is a plan view showing a configuration of the semiconductor device 10 used in the display device 100 according to an embodiment of the present invention. FIG. 5 corresponds to a cross-sectional view when cut with a dash-dot line shown in FIG. 6. Although shown with slightly different dimensions for convenience of explanation, the semiconductor device 10 shown in FIG. 5 and the select transistor 201 shown in FIG. 4 basically have the same structure.

The semiconductor device 10 is arranged above the substrate 500, as shown in FIG. 5. The semiconductor device 10 includes the insulating layer 520, the oxide semiconductor layer 544, the insulating layer 550, a gate electrode 564, an insulating layer 570, an insulating layer 580, a source electrode 591, and a drain electrode 593.

The insulating layer 520 is arranged above the substrate 500. The oxide semiconductor layer 544 is arranged above the insulating layer 520. The oxide semiconductor layer 544 is in contact with the insulating layer 520. A surface in contact with the insulating layer 550 among a main surface of the oxide semiconductor layer 544 is referred to as an upper surface, and a surface in contact with the insulating layer 520 is referred to as a lower surface. In addition, a surface connecting the upper and lower surfaces of the oxide semiconductor layer 544 is referred to as a side surface. The insulating layer 520 functions as a barrier layer that shields impurities that diffuse from the substrate 500 toward the oxide semiconductor layer 544.

The oxide semiconductor layer 544 has light transmittance. In addition, the oxide semiconductor layer 544 is divided into a source region 544S, a drain region 544D, and a channel region 544CH. The channel region 544CH is a region of the oxide semiconductor layer 544 vertically below the gate electrode 564 (that is, a region that overlaps the gate electrode 564). The source region 544S is a region of the oxide semiconductor layer 544 that does not overlap the gate electrode 564 and is closer to the source electrode 591 than the channel region 544CH. The drain region 544D is a region of the oxide semiconductor layer 544 that does not overlap the gate electrode 564 and is closer to the drain electrode 593 than the channel region 544CH. The channel region 544CH corresponds to the channel portion 403a shown in FIG. 4, and the source region 544S and the drain region 544D respectively correspond to the conductive portion 403b shown in FIG. 4.

The gate electrode 564 is composed of a conductive layer and is arranged so as to overlap part of the oxide semiconductor layer 544 via the insulating layer 550. For example, the insulating layer 550 is formed of a silicon oxide layer, and is arranged in contact with the oxide semiconductor layer 544.

The insulating layer 570 and the insulating layer 580 are respectively arranged above the insulating layer 550 and the gate electrode 564. Contact holes 571 and 573 that reach the oxide semiconductor layer 544 are arranged in the insulating layer 570 and the insulating layer 580. The source electrode 591 is in contact with the source region 544S via the contact hole 571. The drain electrode 593 is in contact with the drain region 544D via the contact hole 573.

The oxide semiconductor layer 544 has a polycrystalline structure including a plurality of crystal grains. Although details will be described later, using a Poly-OS (Poly-crystalline Oxide Semiconductor) technique makes it possible to form the oxide semiconductor layer 544 having the polycrystalline structure. The oxide semiconductor itself having the polycrystalline structure may be referred to as Poly-OS, in the following explanation.

The oxide semiconductor layer 544 contains two or more metals including indium, and the proportion of indium in the two or more metals is 50% or more, in the present embodiment. Gallium (Ga), zinc (Zn), aluminum (AI), hafnium (Hf), yttrium (Y), zirconium (Zr), and lanthanoids are used as the metal element other than the indium element. However, the oxide semiconductor layer 544 is not limited to this example and may contain a metal element other than those described above.

In addition, the source region 544S and the drain region 544D may contain an element other than the above metal elements. Although details will be described later, the source region 544S and the drain region 544D have lower resistivity than the channel region 544CH. Such a decrease in resistivity is realized in a process of adding an element such as argon (Ar), phosphorus (P), or boron (B) (hereinafter, referred to as “impurity element”) to the oxide semiconductor layer 544.

The concentration of the impurity element contained in the source region 544S and the drain region 544D is preferably 1×10¹⁸ cm⁻³ or more and 1×10²¹ cm⁻³ or less when measured by SIMS spectrometry (secondary ion-mass spectrometry). In the case where the source region 544S and the drain region 544D contain an impurity element at 1×10¹⁸ cm⁻³ or more and 1×10²¹ cm⁻³ or less, it is presumed that the impurity element was intentionally added by an ion implantation method or an ion doping method. However, the source region 544S and the drain region 544D may contain an impurity element other than argon (Ar), phosphorus (P), or boron (B) at a concentration of less than 1×10¹⁸ cm⁻³. The inclusion of an impurity element in the channel region 544CH affects the properties of the semiconductor device 10. Therefore, the concentration of the impurity element contained in the channel region 544CH is preferably less than 1×10¹⁸ cm⁻³ (more preferably 1×10¹⁶ cm-3 or less).

The gate electrode 564 has a function as a top-gate of the semiconductor device 10. The insulating layer 550 has a function as a gate insulating layer of the semiconductor device 10, and has a function of releasing oxygen by heat treatment in a manufacturing process. The insulating layer 570 and the insulating layer 580 respectively insulate between the gate electrode 564 and the source electrode 591 and between the gate electrode 564 and the drain electrode 593. As a result, parasitic capacitances occurring between the gate electrode 564 and the source electrode 591 and between the gate electrode 564 and the drain electrode 593 can be reduced.

A gate wiring 565 extends in a first direction (direction D1), as shown in FIG. 6. Part of the gate wiring 565 branches toward the second direction (direction D2) and overlaps the oxide semiconductor layer 544. Part of the gate wiring 565 that overlaps the oxide semiconductor layer 544 functions as the gate electrode 564. A length of the region where the oxide semiconductor layer 544 and the gate electrode 564 overlap (that is, the channel region 544CH) in the first direction (direction D1) is a channel length (L), and a length in the second direction (direction D2) is a channel width (W). In addition, the gate wiring 565 shown in FIG. 6 corresponds to the scanning signal line 114 shown in FIG. 3 and FIG. 4. Further, the gate electrode 564 shown in FIG. 5 corresponds to a portion of the scanning signal line 114 shown in FIG. 3 and FIG. 4 that overlaps the oxide semiconductor layer 544.

### [Crystal Structure of Oxide Semiconductor Layer]

The oxide semiconductor layer 544 of the present embodiment include Poly-OS. Although the oxide semiconductor layer 544 will be exemplified in the following explanation, the same explanation can be made for the video signal line 116 (including the intersection portion 116a) composed of the same layer as the oxide semiconductor layer 544.

A particle diameter of the crystal grain included in Poly-OS observed from the upper surface of the oxide semiconductor layer 544 (or a thickness direction of the oxide semiconductor layer 544) is 0.1 μm or more, preferably 0.3 μm or more, and more preferably 0.5 μm or more. For example, the particle diameter of the crystal grain can be obtained using a cross-sectional SEM observation, a cross-sectional TEM observation, an electron back scattered diffraction (EBSD) method, or the like.

The plurality of crystal grains may have one type of crystal structure or may have a plurality of types of crystal structure in Poly-OS. The crystal structure of Poly-OS can be identified using electron diffraction method, an XRD method, or the like. That is, the crystal structure of the oxide semiconductor layer 544 can be identified by the electron diffraction method, the XRD method, or the like.

The oxide semiconductor layer 544 preferably has a cubic crystal structure. The cubic crystal has a high symmetry of the crystal structure, and even when oxygen defects are generated in the oxide semiconductor layer 544, the structure relaxation is unlikely to occur and the crystal structure is stable. The oxide semiconductor layer 544 contains two or more metals including indium, and the proportion of indium in the two or more metals is 50% or more, as described above. The crystal structure of each of the plurality of crystal grains is controlled by increasing the proportion of the indium elements, and the oxide semiconductor layer 544 having the cubic crystal structure can be formed.

The oxide semiconductor layer 544 includes the channel portion 403a corresponding to the channel region 544CH and the conductive portion 403b corresponding to the source region 544S and the drain region 544D, as shown in FIG. 5. The channel portion 403a has a first crystal structure and the conductive portion 403b has a second crystal structure, in the oxide semiconductor layer 544. The conductive portion 403b has a higher electric conductivity than the channel portion 403a, but the second crystal structure is the same as the first crystal structure. In this case, the two crystal structures are the same means that the crystal systems are the same. For example, in the case where the crystal structure of the oxide semiconductor layer 544 is the cubic crystal, the first crystal structure of the channel portion 403a and the second crystal structure of the conductive portion 403b are both cubic crystal and identical. For example, the first crystal structure and the second crystal structure can be identified by a microelectron diffraction method.

In addition, a plane interval d of the first crystal structure and a plane interval d of the second crystal structure are substantially the same in a predetermined crystal orientation. In this case, two plane intervals d are substantially the same means that one plane interval d is 0.95 times or more and 1.05 times or less than the other plane interval d. Alternatively, it means that the two diffraction patterns are almost identical in the microelectron diffraction method.

There may be no grain boundaries between the channel portion 403a and the conductive portion 403b. In addition, the channel portion 403a and the conductive portion 403b may be included in one crystal grain. In other words, the change from the channel portion 403a to the conductive portion 403b may be a contiguous change in the crystal structure.

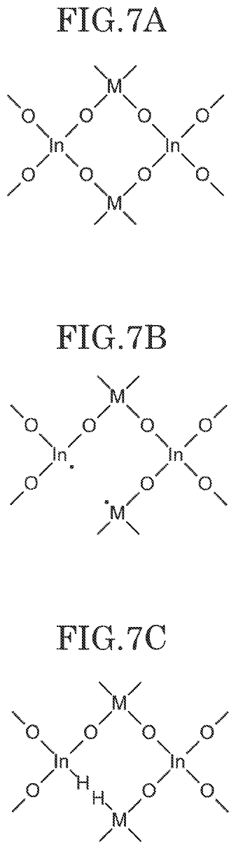

FIG. 7A to FIG. 7C are schematic diagrams for explaining a bonding state of Poly-OS contained in the conductive portion 403b of the oxide semiconductor layer 544. FIG. 7A to FIG. 7C show Poly-OS containing an indium atom (In atom) and a metal atom (M atom) that is different from In atoms.

Each of the In atom and the metal atom M is bonded to an oxygen atom (O atom) in the Poly-OS shown in FIG. 7A. In order to increase the electric conductivity than the channel portion 403a, the bond between the In atom and the O atom (or the metal atom M and the O atom) is broken in the conductive portion 403b, and oxygen defects in which the O atom is desorbed are generated (see FIG. 7B), in the crystal structure of the Poly-OS shown in FIG. 7A. Since the Poly-OS contains a crystal grain with large particle diameter, long-range order is easily maintained. Therefore, even if an oxygen defect is generated, the structural relaxation hardly occurs, and the positions of the In atom and the metal atom M hardly change. In the case where hydrogen is present in the condition shown in FIG. 7B, a dangling bond of the In atom and a dangling bond of the metal atom M in the oxygen defects are bonded to the hydrogen atom (H atom) and stabilized (see FIG. 7C). Since the H atom in the oxygen defects functions as a donor, the carrier concentration of the conductive portion 403b increases.

In addition, even if the H atom is bonded in the oxygen defects, the positions of the In atom and the metal atom M hardly change in the Poly-OS, as shown in FIG. 7C. Therefore, the second crystal structure of the conductive portion 403b does not change from the crystal structure of the Poly-OS without oxygen defects. That is, the second crystal structure of the conductive portion 403b is the same as the first crystal structure of the channel portion 403a.

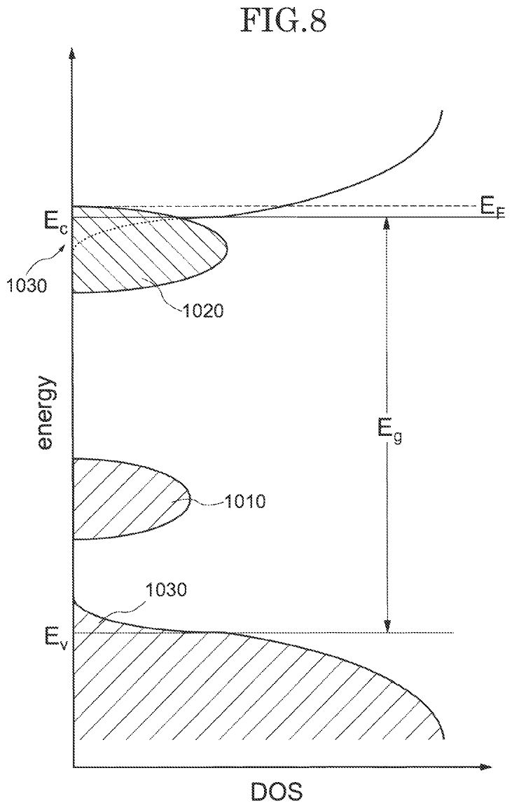

FIG. 8 is a band diagram for explaining a band structure of the conductive portion 403b of the oxide semiconductor layer 544.

A first energy level 1010 and a second energy level 1020 are included in a bandgap E_{g} in the Poly-OS of the conductive portion 403b as shown in FIG. 8. In addition, a tail level 1030 is included in the vicinity of an energy level Ev at the upper end of the valence band and in the vicinity of an energy level E_{C} at the lower end of the conduction band. The first energy level 1010 is a deep trap level present in the bandgap E_{g} and is attributed to oxygen defects. The second energy level 1020 is a donor level present in the vicinity of the lower end of the conduction band and is attributed to the hydrogen atom bonded within the oxygen defects. The tail level 1030 is caused by a disturbance of long-range order.

Although the Poly-OS in the conductive portion 403b contains oxygen defects, it has the crystal structure, and long-range order is maintained. In addition, hydrogen atoms can be bonded within the oxygen defects without causing a structural disturbance, in the Poly-OS in the conductive portion 403b. Therefore, it is possible to increase a DOS of the second energy level 1020 while suppressing Density of State (DOS) of the tail level 1030. Therefore, the DOS of the second energy level 1020 is larger than the DOS of the tail level 1030 in the vicinity of the lower end of the conduction band, and the DOS of the second energy level 1020 can extend beyond the energy level E_{C} at the lower end of the conduction band. That is, the Fermi level E_{F} exceeds the energy level E_{C} at the lower end of the conduction band, and the Poly-OS in the conductive portion 403b has metal properties.

The Poly-OS in the conductive portion 403b has metal properties unlike the conventional oxide semiconductor, as described above. Therefore, the conductive portion 403b can be made sufficiently low in resistance by generating oxygen defects. The sheet resistance of the conductive portion 403b is 1000 Ω/sq. or less, preferably 500 Ω/sq. or less, and more preferably 250 Ω/sq. or less.

Since it is possible to sufficiently reduce the resistance of the source region 544S and the drain region 544D (for example, the conductive portion 403b) of the oxide semiconductor layer 544, so that the conductive portion 403b can be used as the wiring, as described above, in the present embodiment. The video signal line 116 shown in FIG. 3 and FIG. 4 utilizes such features of the oxide semiconductor layer 544.

A light-shielding layer may be arranged between the substrate 500 and the oxide semiconductor layer 544 in the present embodiment. Arranging the light-shielding layer in a region overlapping the channel region 544CH makes it possible to suppress the characteristic variation of the semiconductor device 10 due to the irradiation of light to the channel region 544CH. The semiconductor device 10 may have the dual-gate structure by using the light-shielding layer as the gate electrode, in this case.

### [Method for Manufacturing Semiconductor Device]

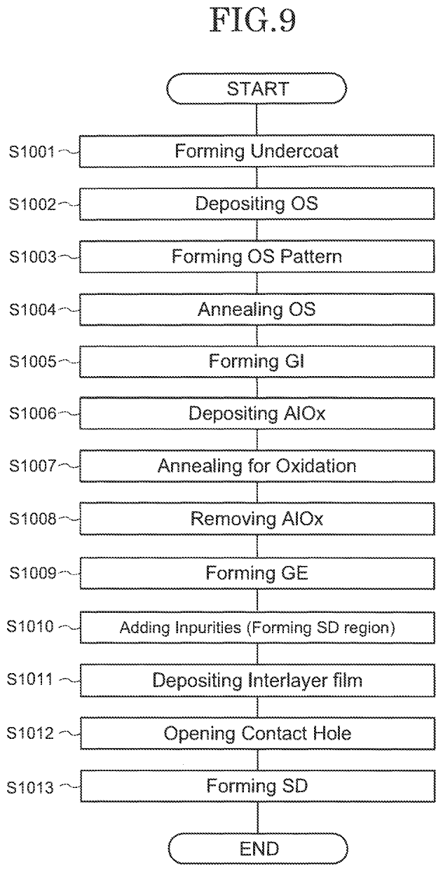

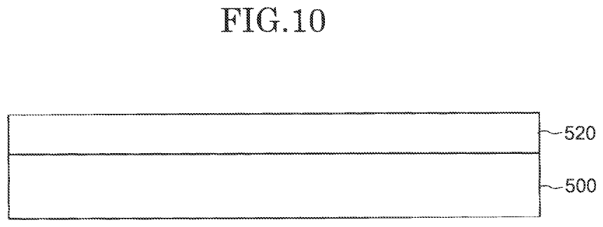

A method for manufacturing the semiconductor device 10 used in the display device 100 according to an embodiment of the present invention will be described with reference to FIG. 9 to FIG. 18. FIG. 9 is a sequence diagram showing a method for manufacturing the semiconductor device 10 used in the display device 100 according to an embodiment of the present invention. FIG. 10 to FIG. 18 are cross-sectional views showing a method for manufacturing the semiconductor device 10 used in the display device 100 according to an embodiment of the present invention.

First, the insulating layer 520 is formed above the substrate 500 (step S1001) as shown in FIG. 9 and FIG. 10.

A rigid substrate having light transmittance such as a glass substrate, a quartz substrate, a sapphire substrate, or the like is used as the substrate 500. In the case where the substrate 500 needs to have flexibility, a substrate containing resin such as a polyimide substrate, an acryl substrate, a siloxane substrate, or a fluororesin substrate is used as the substrate 500. In the case where a substrate containing resin is used as the substrate 500, an impurity element may be introduced into the resin in order to improve the heat resistance of the substrate 500.

The insulating layer 520 is formed by a CVD (Chemical Vapor Deposition) method or a sputtering method. A typical insulating material is used as the insulating layer 520. For example, an inorganic insulating material such as silicon oxide (SiOₓ), silicon oxynitride (SiOₓN_{y}), silicon nitride (SiNₓ), silicon nitride oxide (SiNₓO_{y}), aluminum oxide (AlOₓ), aluminum oxynitride (AlOₓN_{y}), aluminum nitride oxide (AlNₓO_{y}), and aluminum nitride (AlNₓ) is used as the insulating layer 520.

SiOₓN_{y} and AlOₓN_{y} are silicon compound and aluminum compound containing a smaller proportion (x>y) of nitrogen (N) than oxygen (O). SiNₓO_{y} and AlNₓO_{y} are silicon compound and aluminum compound containing a smaller proportion of oxygen than nitrogen (x>y).

The insulating layer 520 is formed of a single-layer structure or a stacked structure. In the case where the insulating layer 520 is a stacked structure, it is preferable to arrange an insulating material containing nitrogen closer to the substrate 500 and then form an insulating material containing oxygen. For example, using an insulating material containing nitrogen makes it possible to block impurities that diffuse from the substrate 500 toward the oxide semiconductor layer 544. In addition, using an insulating material containing oxygen makes it possible to release oxygen by heat treatment. For example, the temperature of the heat treatment in which the insulating material containing oxygen releases oxygen is 600° C. or lower, 500° C. or lower, 450° C. or lower, or 400° C. or lower. That is, for example, the insulating material containing oxygen releases oxygen at the heat treatment temperature performed in the manufacturing process of the semiconductor device 10 when the glass substrate is used as the substrate 500. For example, silicon nitride is used as the insulating material containing nitrogen in the present embodiment. For example, silicon oxide is used as the insulating material containing oxygen.

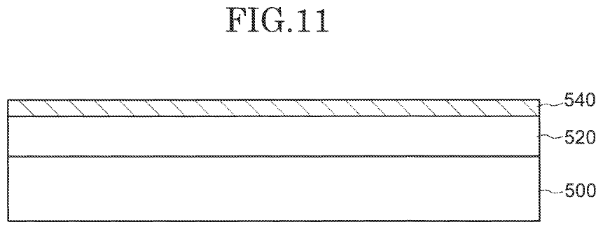

Next, an oxide semiconductor layer 540 is formed above the insulating layer 520 (step S1002) as shown in FIG. 9 and FIG. 11. The oxide semiconductor layer 540 is deposited by the sputtering method or an atomic layer deposition (ALD) as shown in FIG. 9 and FIG. 11. For example, a thickness of the oxide semiconductor layer 540 is 10 nm or more and 100 nm or less, 15 nm or more and 70 nm or less, or 20 nm or more and 40 nm or less.

Metal oxide having semiconductor properties can be used as the oxide semiconductor layer 540. For example, an oxide semiconductor containing two or more metals containing indium (In) is used as the oxide semiconductor layer 540. In addition, the proportion of indium in the two or more metals is 50% or more. Gallium (Ga), zinc (Zn), aluminum (Al), hafnium (Hf), yttrium (Y), zirconia (Zr), or lanthanoids are used as the oxide semiconductor layer 540 in addition to indium. Elements other than those described above may be used as the oxide semiconductor layer 540. A metal oxide (IGO-based oxide semiconductor) containing indium (In) and gallium (Ga) is used as the oxide semiconductor layer 540 in the present embodiment.

In the case where the oxide semiconductor layer 540 is crystallized by an OS annealing (step S1004) described later, the oxide semiconductor layer 540 after the deposition and before the OS annealing is preferably amorphous (with a state in which the oxide semiconductor has few crystalline components). That is, the deposition method of the oxide semiconductor layer 540 is preferably such that the oxide semiconductor layer 540 immediately after the deposition does not crystallize as much as possible. For example, in the case where the oxide semiconductor layer 540 is deposited by the sputtering method, a condition that the oxide semiconductor layer 540 does not crystallize can be realized by controlling the temperature of an object to be deposited (the substrate 500 and the structure formed thereon).

Since ions generated in a plasma and atoms bounced back by a sputtering target collide with the object to be deposited when the deposition is performed on the object to be deposited by the sputtering method, the temperature of the object to be deposited increases with the deposition treatment. When the temperature of the object to be formed during the deposition treatment increases, microcrystals are contained in the oxide semiconductor layer 540 in the state immediately after the deposition, and crystallization due to subsequent OS annealing is inhibited. In order to control the temperature of the object to be deposited as described above, for example, the deposition can be performed while cooling the object to be deposited. For example, the object to be deposited can be cooled from the surface opposite to the depositing surface so that the temperature of the depositing surface of the object to be deposited (hereinafter, referred to as “deposition temperature”) is 100° C. or lower, 70° C. or lower, 50° C. or lower, or 30° C. or lower. Forming the oxide semiconductor layer 540 while the object to be formed is cooled makes it possible to form the oxide semiconductor layer 540 with few crystalline components in the state immediately after the deposition, as described above.

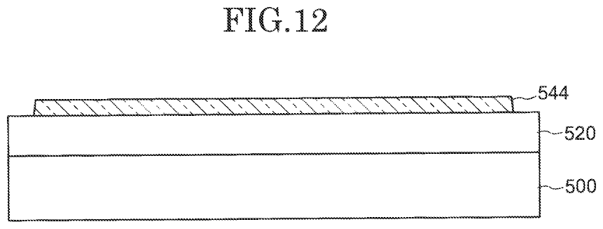

Next, a pattern of the oxide semiconductor layer 540 is formed by photolithography (step S1003) as shown in FIG. 9 and FIG. 12. Although not shown, a resist mask is formed above the oxide semiconductor layer 540, and the oxide semiconductor layer 540 is etched using the resist mask. Although not shown, a pattern for use as the video signal line 116 is also formed at the same time when the pattern of the oxide semiconductor layer 540 is formed.

Either wet etching or dry etching may be used when the oxide semiconductor layer 540 is etched. In the case of wet etching, etching can be performed using an acidic etchant. For example, oxalic acid or hydrofluoric acid can be used as the etchant.

The oxide semiconductor layer 540 is preferably patterned before the OS annealing performed in step S1004. If the oxide semiconductor layer 540 is crystallized by the OS annealing, it tends to be difficult to etch. In addition, even if the oxide semiconductor layer 540 is damaged by etching, the damage can be repaired by the OS annealing.

The heat treatment is performed on the oxide semiconductor layer 540 (OS annealing) after the oxide semiconductor layer 540 is patterned (step S1004). The oxide semiconductor layer 540 is held at a predetermined reached temperature for a predetermined time in the OS annealing. The predetermined arrival temperature is 300° C. or higher and 500° C. or lower, preferably 350° C. or higher and 450° C. or lower. In addition, the holding time at the reached temperature is 15 minutes or more and 120 minutes or less, preferably 30 minutes or more and 60 minutes or less. The oxide semiconductor layer 540 is crystallized by performing the OS annealing, and the oxide semiconductor layer 544 having a polycrystalline structure is formed.

In addition, in the case where the display device 100 of the present embodiment is manufactured, the oxide semiconductor layer 544 of the select transistor 201 is formed, and at the same time, a wiring pattern composed of the oxide semiconductor layer for use as the video signal line 116 is formed. Therefore, the wiring pattern formed by this process has the same crystal structure as the oxide semiconductor layer 544.

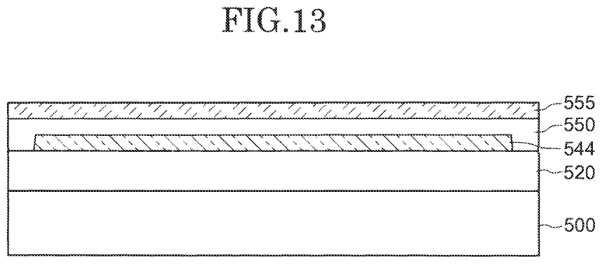

Next, the insulating layer 550 is formed above the oxide semiconductor layer 544 (step S1005) as shown in FIG. 9 and FIG. 13.

The deposition method and the insulating material of the insulating layer 550 may refer to the description of the insulating layer 520. For example, although a thickness of the insulating layer 550 is 50 nm or more and 150 nm or less in the present embodiment, it is not limited to this.

An insulating material containing oxygen is preferably used as the insulating layer 550. In addition, a less defective insulating layer is preferably used as the insulating layer 550. For example, in the case where the composition ratio of oxygen in the insulating layer 550 is compared with the composition ratio of oxygen in an insulating layer having the same composition ratio as the insulating layer 550 (hereinafter referred to as “the other insulating layer”), the composition ratio of oxygen in the insulating layer 550 is closer to the stoichiometric ratio with respect to the insulating layer than the composition ratio of oxygen in the other insulating layer. For example, in the case where silicon oxide (SiOₓ) is used for each of the insulating layer 550 and the insulating layer 580, the composition ratio of oxygen in the silicon oxide used as the insulating layer 550 is closer to the stoichiometric ratio of silicon oxide compared with the composition ratio of oxygen in the silicon oxide used as the insulating layer 580. For example, a layer in which no defects are observed when evaluated by an electron-spin resonance (ESR) method may be used as the insulating layer 550.

In order to form a less defective insulating layer as the insulating layer 550, the insulating layer 550 may be deposited at a deposition temperature of 350° C. or higher. In addition, an oxygen implantation treatment may be performed on part of the insulating layer 550 after the insulating layer 550 is deposited. In order to form the less defective insulating layer as the insulating layer 550, a silicon oxide layer is formed at a deposition temperature of 350° C. or higher in the present embodiment.

Next, a metal oxide layer 555 containing aluminum as a main component is formed above the insulating layer 550 (step S1006) as shown in FIG. 9 and FIG. 13.

The metal oxide layer 555 is formed by the sputtering method. Oxygen is implanted into the insulating layer 550 by depositing the metal oxide layer 555. For example, an inorganic insulating layer such as aluminum oxide (AlOₓ), aluminum oxynitride (AlOₓN_{y}), aluminum nitride oxide (AlNₓO_{y}), and aluminum nitride (AlNₓ) are used as the metal oxide layer containing aluminum as a main component. The “metal oxide layer containing aluminum as a main component” means that the proportion of aluminum contained in the metal oxide layer 555 is 1% or more of the total amount of the metal oxide layer 555. The proportion of aluminum contained in the metal oxide layer 555 may be 5% or more and 70% or less, 10% or more and 60% or less, or 30% or more and 50% or less of the entire metal oxide layer 555. The above proportion may be a mass ratio or a weight ratio.

For example, the thickness of the metal oxide layer 555 is 5 nm or more and 100 nm or less, 5 nm or more and 50 nm or less, 5 nm or more and 30 nm or less, or 7 nm or more and 15 nm or less. Aluminum oxide is used as the metal oxide layer 555 in the present embodiment. Aluminum oxide has a high barrier property against gas. The aluminum oxide used as the metal oxide layer 555 suppresses the oxygen implanted into the insulating layer 550 from diffusing outward when the metal oxide layer 555 is formed in the present embodiment.

For example, in the case where the metal oxide layer 555 is formed by the sputtering method, a process gas used in sputtering remains in the film of the metal oxide layer 555. For example, in the case where Ar is used as the process gas for sputtering, Ar may remain in the film of the metal oxide layer 555. The remaining Ar can be detected by a SIMS (Secondary Ion Mass Spectrometry) analyses on the metal oxide layer 555.

A heat treatment (oxidation annealing) for supplying oxygen to the oxide semiconductor layer 544 is performed in a state in which the insulating layer 550 is formed above the oxide semiconductor layer 544 and the metal oxide layer 555 is formed above the insulating layer 550 (step S1007).

A large number of oxygen defects occur on the upper surface and the side surface of the oxide semiconductor layer 544 in the process from the deposition of the oxide semiconductor layer 544 to the deposition of the insulating layer 550 above the oxide semiconductor layer 544. Oxygen emitted from the insulating layer 550 is supplied to the upper surface and the side surface of the oxide semiconductor layer 544 by the oxidation annealing, and the oxygen defects inside the oxide semiconductor layer 544 is repaired.

Since the oxygen implanted into the insulating layer 550 is blocked by the metal oxide layer 555 in the above-described oxidation annealing, release into the atmosphere is suppressed. Therefore, oxygen is efficiently supplied to the oxide semiconductor layer 544 by the oxidation annealing performed in step S1007, and oxygen defects inside the oxide semiconductor layer 544 are repaired.

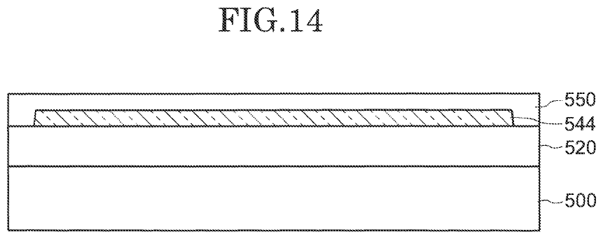

Next, the metal oxide layer 555 is etched (removed) after the oxidation annealing (step S1008) as shown in FIG. 9 and FIG. 14. Either wet etching or dry etching may be used to etch the metal oxide layer 555. For example, dilute hydrofluoric acid (DHF) is used as the etchant for wet etching. The metal oxide layer 555 formed on the entire surface of the insulating layer 550 is removed by the etching. In other words, the metal oxide layer 555 is removed without using a mask. In other words, the etching performed in step S1008 removes all the metal oxide layer 555 in a region overlapping the oxide semiconductor layer 544 formed in one certain pattern in at least a plan view.

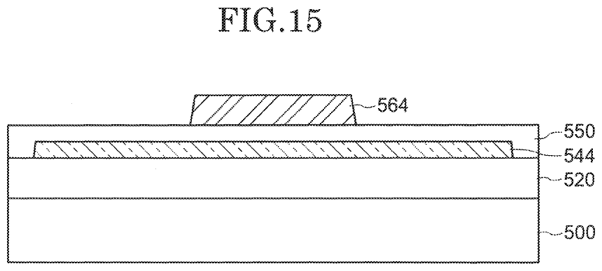

Next, the gate electrode 564 is formed above the insulating layer 550 (step S1009) as shown in FIG. 9 and FIG. 15. The gate electrode 564 is formed by patterning a metal layer formed by the sputtering method or an atomic layer deposition method. The gate electrode 564 is formed to be in contact with the exposed the insulating layer 550 by removing the metal oxide layer 555, as described above.

The gate electrode 564 corresponds to the scanning signal line 114 shown in FIG. 3 and FIG. 4 as described above. Therefore, although not shown, a wiring pattern that functions as the scanning signal line 114 when forming the gate electrode 564 is also formed.

A typical metal material is used as the material of the gate electrode 564. Examples of the metal material include aluminum (Al), titanium (Ti), chromium (Cr), cobalt (Co), nickel (Ni), molybdenum (Mo), hafnium (Hf), tantalum (Ta), tungsten (W), bismuth (Bi), silver (Ag), copper (Cu), and alloys or compounds thereof. The above-described material may be used in a single-layer structure or may be used in a stacked structure.

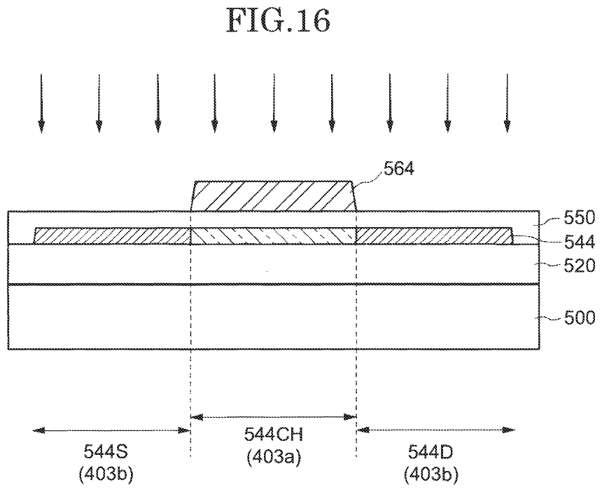

Next, the source region 544S and the drain region 544D of the oxide semiconductor layer 544 are formed (step S1010) with a state in which the gate electrode 564 is formed, as shown in FIG. 9 and FIG. 16. Specifically, an impurity element is implanted (added) into the oxide semiconductor layer 544 through the insulating layer 550 using the gate electrode 564 as a mask by ion implantation or ion doping. For example, an impurity element such as argon (Ar), phosphorus (P), or boron (B) is implanted into part of the oxide semiconductor layer 544 not covered with the gate electrode 564, in step S1010.

Oxygen vacancies are formed in the region of the oxide semiconductor layer 544 into which the impurity element is implanted. The resistance is reduced to a level that can function as a conductive layer by forming a donor level where hydrogen is bonded to the oxygen vacancies. That is, since the impurity element is implanted into the oxide semiconductor layer 544 in step S1010, the conductive portion 403b (the source region 544S and the drain region 544D) is formed in a region not covered with the gate electrode 564. On the other hand, the channel portion 403a (the channel region 544CH) is formed in a region of the oxide semiconductor layer 544 covered with the gate electrode 564. Since the gate electrode 564 functions as a mask, no impurity element is implanted into the channel portion 403a. The resistivity of the conductive portion 403b is lower than the resistivity of the channel portion 403a.

In addition, in the case where the display device 100 of the present embodiment is manufactured, impurities are implanted into the oxide semiconductor layer 544, and at the same time, impurities are also implanted into the wiring pattern (wiring pattern functioning as the video signal line 116) formed of the oxide semiconductor layer. As a result of this implantation, the wiring pattern is formed as an oxide semiconductor layer having the same sheet resistance or electric conductivity as that of the conductive portion 403b. That is, the video signal line 116 composed of the oxide semiconductor layer is formed by the process shown in FIG. 16.

However, if the above ion implantation is performed with the scanning signal line 114 arranged above the wiring pattern functioning as the video signal line 116, the impurity element is not added to the wiring pattern overlapping the scanning signal line 114, and the resistance of the wiring pattern cannot be reduced. Therefore, part of the video signal line 116 (the intersection portion 116a illustrated in FIG. 3 and FIG. 4) is formed differently from the process of manufacturing the semiconductor device 10 in the present embodiment. This point will be described later.

Since the impurity element is implanted into the insulating layer 550 into the oxide semiconductor layer 544 in the present embodiment, not only the source region 544S and the drain region 544D but also the insulating layer 550 contains an impurity element such as argon (Ar), phosphorus (P), or boron (B). Further, the insulating layer 520 located below the oxide semiconductor layer 544 or the insulating layer 550 also contains an impurity element such as argon (Ar), phosphorus (P), or boron (B).

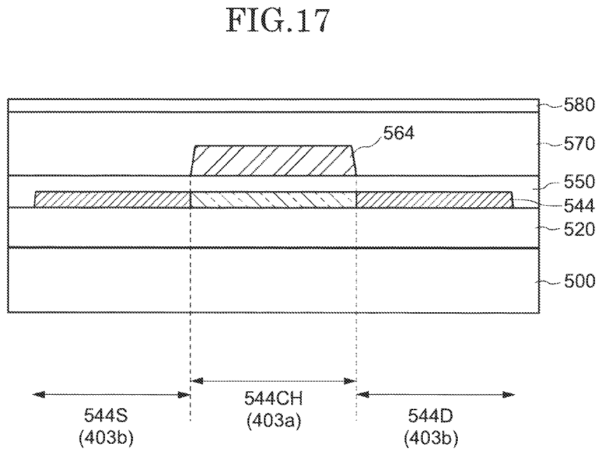

Next, the insulating layers 570 and 580 are formed above the insulating layer 550 and the gate electrode 564 (step S1011) as shown in FIG. 9 and FIG. 17.

The deposition method and insulating materials of the insulating layers 570 and 580 may refer to the description of the insulating layer 520. The thickness of the insulating layer 570 is 50 nm or more and 500 nm or less. The thickness of the insulating layer 580 is 50 nm or more and 500 nm or less. For example, a silicon nitride layer is formed as the insulating layer 570, and a silicon oxide layer is formed as the insulating layer 580, in the present embodiment. The insulating layers 570 and 580 are formed by a plasma CVD method at a deposition temperature of 350° C. or higher and 400° C. or lower.

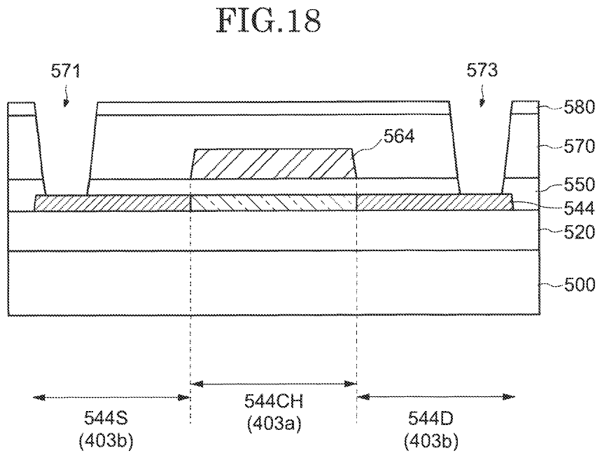

Next, the contact holes 571 and 573 are formed in the insulating layer 550 and the insulating layers 570 and 580 (step S1012) as shown in FIG. 9 and FIG. 18. The source region 544S is exposed by the contact hole 571, and the drain region 544D is exposed by the contact hole 573. The source region 544S and the drain region 544D are exposed by the contact holes 571 and 573, and then the source electrode 591 and the drain electrode 593 shown in FIG. 5 are formed (step S1013). The semiconductor device 10 shown in FIG. 5 is completed through the above-described process.

For example, the source electrode 591 and the drain electrode 593 are formed by the sputtering method. The source electrode 591 and the drain electrode 593 can be formed using a typical metal material. For example, aluminum (AI), titanium (Ti), chromium (Cr), cobalt (Co), nickel (Ni), molybdenum (Mo), hafnium (Hf), tantalum (Ta), tungsten (W), bismuth (Bi), silver (Ag), copper (Cu), and alloys or compounds thereof can be used as the metal material. The source electrode 591 and the drain electrode 593 may have a single-layer structure or a stacked structure.

Electric properties (specifically, field-effect mobility) having a mobility of 30 cm²/Vs or more, 35 cm²/Vs or more, or 40 cm²/Vs or more can be obtained in a range where a channel length L of the channel region 544CH is 2 μm or more and 4 μm or less and a channel width of the channel region 544CH is 2 μm or more and 25 μm or less, in the semiconductor device 10 manufactured by the above-described manufacturing method. The field-effect mobility in the present embodiment is the field-effect mobility in a saturated region of the semiconductor device 10, and the potential difference (Vd) between the source electrode and the drain electrode indicates the maximum value of the field-effect mobility in a region where the value obtained by subtracting the threshold voltage (Vth) of the semiconductor device 10 from the voltage (Vg) supplied to the gate electrode (Vg−Vth).

The resistivity of the conductive portion 403b constituting the source region 544S and the drain region 544D is sufficiently low in the semiconductor device 10 of the present embodiment. Therefore, an oxide semiconductor layer composed of the same layer as the conductive portion 403b can be used as a wiring (specifically, the video signal line 116). Since the oxide semiconductor has light transmittance, if the oxide semiconductor can be used as the wiring material as in the present embodiment, it is very advantageous to improve the aperture ratio of the display portion 110 in the display device 100.

### [Method for Manufacturing Pixel Structure]

If the ion implantation of the impurity element is performed with the state in which the scanning signal line 114 intersects the wiring pattern composed of the oxide semiconductor layer, the impurity element is not added to the wiring pattern because the scanning signal line 114 becomes the mask, and it is not possible to reduce the resistance in part of the wiring pattern (a part intersecting the scanning signal line 114), as described above. Therefore, the resistance reduction of the intersection portion 116a of the video signal line 116 is realized differently from the other parts, in the present embodiment. Hereinafter, a method for manufacturing a pixel structure will be described.

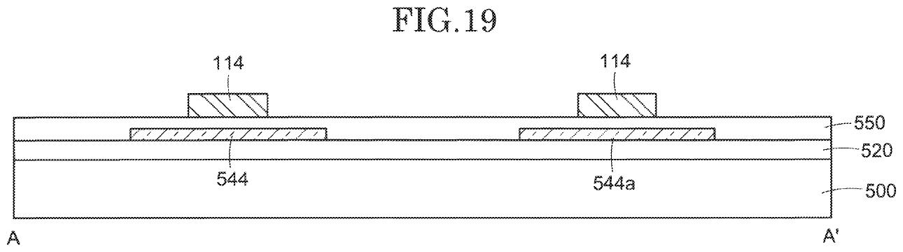

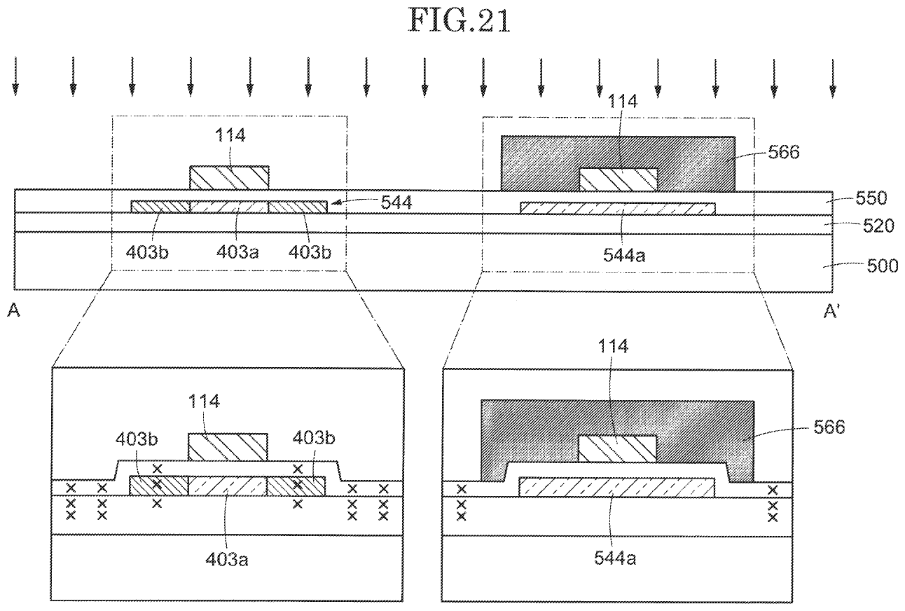

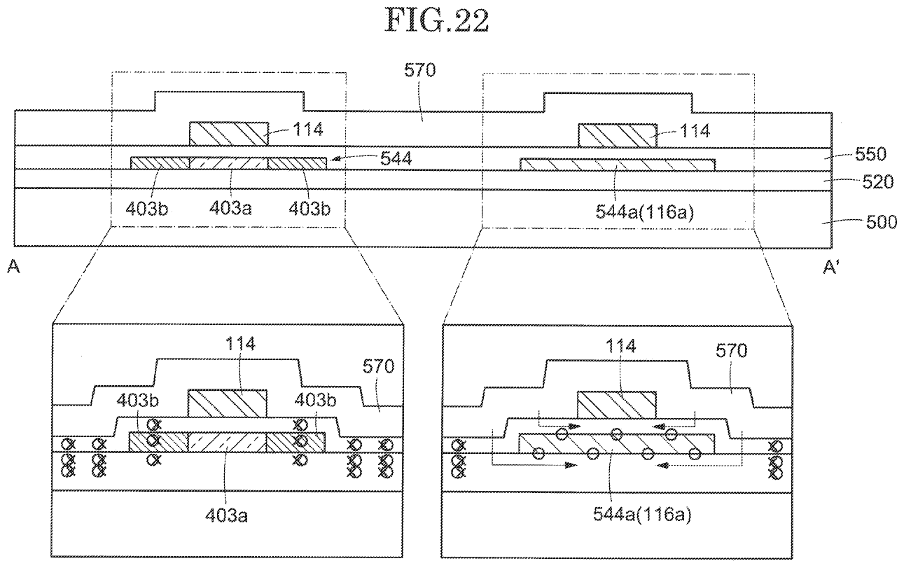

FIG. 19 to FIG. 22 are cross-sectional views showing a method for manufacturing the display device 100 according to an embodiment of the present invention. Specifically, FIG. 19 to FIG. 22 each correspond to a cross-sectional view obtained by cutting the pixel structure shown in FIG. 3 with A-A′. In addition, FIG. 21 and FIG. 22 also show enlarged views of each stacked structure for convenience of explanation.

First, the process proceeds to the state shown in FIG. 15 according to the sequence diagram shown in FIG. 9. The oxide semiconductor layers 544 and 544a are formed above the insulating layer 520 as shown in FIG. 19. The oxide semiconductor layer 544 functions as an active layer of the semiconductor device 10. The oxide semiconductor layer 544a is composed of the same layer as the oxide semiconductor layer 544, and is the wiring pattern for use as the video signal line 116.

The scanning signal line 114 is respectively formed above the oxide semiconductor layers 544 and 544a via the insulating layer 550. In this case, the scanning signal line 114 that overlaps the oxide semiconductor layer 544 functions as a gate electrode of the semiconductor device 10. The scanning signal line 114 overlapping the oxide semiconductor layer 544a merely intersects the oxide semiconductor layer 544a as shown in FIG. 3.

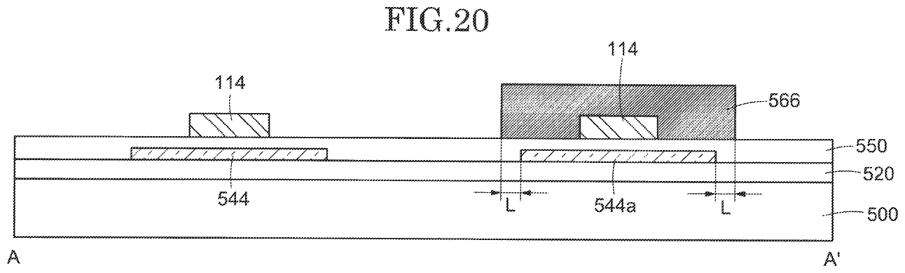

Next, a resist mask 566 is formed so as to cover the oxide semiconductor layer 544a as shown in FIG. 20. The resist mask 566 is arranged so as not to add the impurity element to the oxide semiconductor layer 544a in an ion-implantation process to be described later. Therefore, it is desirable to form the resist mask 566 in a size that ensures adequate margins with respect to the size of the oxide semiconductor layer 544a. For example, as shown in FIG. 20, the resist mask 566 is arranged so as to cover the oxide semiconductor layer 544a from an end portion (edge) to the outer side by a predetermined distance L.

Next, the impurity element is added to part of the oxide semiconductor layer 544 by the ion implantation as shown in FIG. 21. This process corresponds to S1010 of FIG. 9. The condition and the like of the ion implantation are the same as those of the process shown in FIG. 16. The channel portion 403a and the conductive portion 403b are formed in the oxide semiconductor layer 544 in the process of adding the impurity element as described above. In this case, since the impurity element is added to the oxide semiconductor layer 544 using the scanning signal line 114 (gate electrode) as the mask, the channel portion 403a and the conductive portion 403b are formed in self-alignment.

It is considered that a bond between silicon and hydrogen is broken in the process of adding an impurity element and hydrogen is generated in the insulating layer 550 in the above-described process of adding the impurity element. Hydrogen generated in the insulating layer 550 combines with oxygen vacancies within the oxide semiconductor layer 544 to form shallow donor levels. Therefore, it is considered that the conductive portion 403b is reduced in resistance at the time when the process shown in FIG. 21 is performed.

The symbol “x” in the enlarged view shown in FIG. 21 schematically indicates a defect formed in the film by the ion-implantation process. The defect is formed in part of the insulating layer 520, part of the oxide semiconductor layer 544 (the conductive portion 403b), and part of the insulating layer 550, as shown in FIG. 21. Specifically, the defect is not formed in part of the insulating layer 520, the oxide semiconductor layer 544, and the insulating layer 550 that overlaps the scanning signal line 114, and the defect is formed in part that does not overlap the scanning signal line 114. The formation of defects is caused by the addition of impurity elements. In other words, among the stacked structure composed of the insulating layer 520, the oxide semiconductor layer 544, and the insulating layer 550, it can be said that the impurity element is contained in each layer in a region (that is, a region where defects exist) that does not overlap the scanning signal line 114, and the impurity element is not contained in each layer in a region that overlaps the scanning signal line 114.

On the other hand, since the resist mask 566 is arranged above the oxide semiconductor layer 544a, no impurity element is added to the oxide semiconductor layer 544a. Therefore, the oxide semiconductor layer 544a generally maintain the same state as the channel portion 403a (a state in which resistivity is higher than that of the conductive portion 403b), and do not contain any impurity elements. That is, it can be said that the stacked structure composed of the insulating layer 520, the oxide semiconductor layer 544a, and the insulating layer 550 does not contain the impurity element in any of the layers in the region overlapping and not overlapping the scanning signal line 114.

In addition, the insulating layer 520 and the insulating layer 550 located within a predetermined range from the end portion of the oxide semiconductor layer 544a to the outer side do not contain any impurity elements. As described above, in the case where the process shown in FIG. 21 is performed, the insulating layer 520 and the insulating layer 550 located within a predetermined range from the end portion of the oxide semiconductor layer 544a to the outer side do not contain impurity elements, whereas the insulating layer 520 and the insulating layer 550 located within a predetermined range from the end portion of the oxide semiconductor layer 544 to the outer side (inside the range separated by the predetermined distance L) contain impurity elements, and they have different configurations.

Next, the insulating layer 570 is formed above the scanning signal line 114 as shown in FIG. 22. A silicon nitride layer is formed as the insulating layer 570 as described above in the present embodiment. The insulating layer 570 is formed by the plasma CVD method at a deposition temperature of 350° C. or higher and 400° C. or lower. Typically, the silicon nitride layer formed by the plasma CVD method contains a large amount of hydrogen. Hydrogen contained in the insulating layer 570 is used to reduce the resistance of the oxide semiconductor layer 544a in the present embodiment.

Since the temperature during deposition is 350° C. or higher, hydrogen contained in the silicon nitride layers diffuses through the insulating layer 520 and the insulating layer 550, in the present embodiment. The symbol “o” in the enlarged view shown in FIG. 22 indicates hydrogen diffused from the insulating layer 570 or hydrogen generated and diffused inside the insulating layer 520 or the insulating layer 550 by the ion-implantation process.

A large number of defects (mainly silicon dangling bonds) indicated by “x” is formed in the insulating layers 520 and 550 around the oxide semiconductor layer 544, so that diffused hydrogen is trapped by bonding with the defects, as shown in the enlarged view of FIG. 22. Therefore, most of the hydrogen diffused around the oxide semiconductor layer 544 does not reach the channel portion 403a, and the reduction in resistance due to the hydrogenation of the channel portion 403a does not occur.

On the other hand, the diffused hydrogen reaches the entire oxide semiconductor layer 544a because no defects are formed in the insulating layers 520 and 550 around the oxide semiconductor layer 544a. As a result, oxygen vacancies within the oxide semiconductor layer 544a combine with the diffused hydrogen to form shallow donor levels. That is, the oxide semiconductor layer 544a is substantially entirely hydrogenated and reduced in resistance. The oxide semiconductor layer 544a with low resistance in such a process functions as the intersection portion 116a shown in FIG. 3. Since almost the entire oxide semiconductor layer 544a is hydrogenated as described above, the oxide semiconductor layer 544a (that is, the intersection portion 116a) can be said to have the same resistivity in the parts overlapping and not overlapping the scanning signal line 114.

In the case where the ion-implantation process for forming the conductive portion 403b is performed, the resist mask is arranged at a portion where the scanning signal line 114 and the video signal line 116 intersect (a portion corresponding to the intersection portion 116a), as described above, in the present embodiment. As a result, part of the wiring pattern (the oxide semiconductor layer 544a) used as the video signal line 116 that overlaps the scanning signal line 114 can be sufficiently hydrogenated, and consequently, it is possible to realize a lower resistance of the intersection portion 116a.

The video signal line 116 is formed in the same layer as the oxide semiconductor layer 544 functioning as the active layer of the semiconductor device 10, in the present embodiment. Therefore, most of the video signal line 116 has the same resistivity as the conductive portion 403b functioning as the source region or drain region of the semiconductor device 10. However, the intersection portion 116a is formed as part of the video signal line 116 with respect to part where the scanning signal line 114 and the video signal line 116 intersect, in the present embodiment. The intersection portion 116a is a portion in which the oxide semiconductor layer is reduced in resistance by hydrogenation, unlike the conductive portion 403b in which the oxide semiconductor layer is reduced in resistance by the ion implantation. Therefore, resistivity of the intersection portion 116a is lower than that of the channel portion 403a.

### Second Embodiment

An example in which the part of the video signal line 116 that intersects the scanning signal line 114 is reduced in resistance in a method that is different from that of the first embodiment will be described in the present embodiment. The same components as those of the first embodiment will be described with reference to the same reference signs in the drawings, and the description will be omitted, focusing on differences from the first embodiment in the following description.

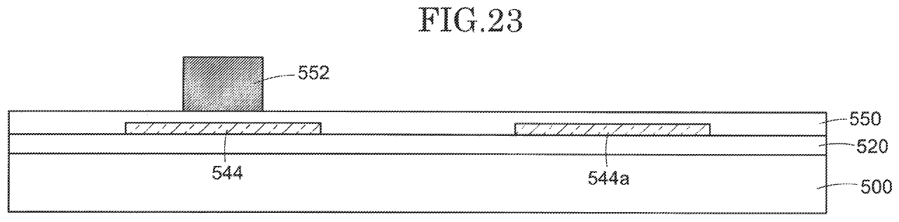

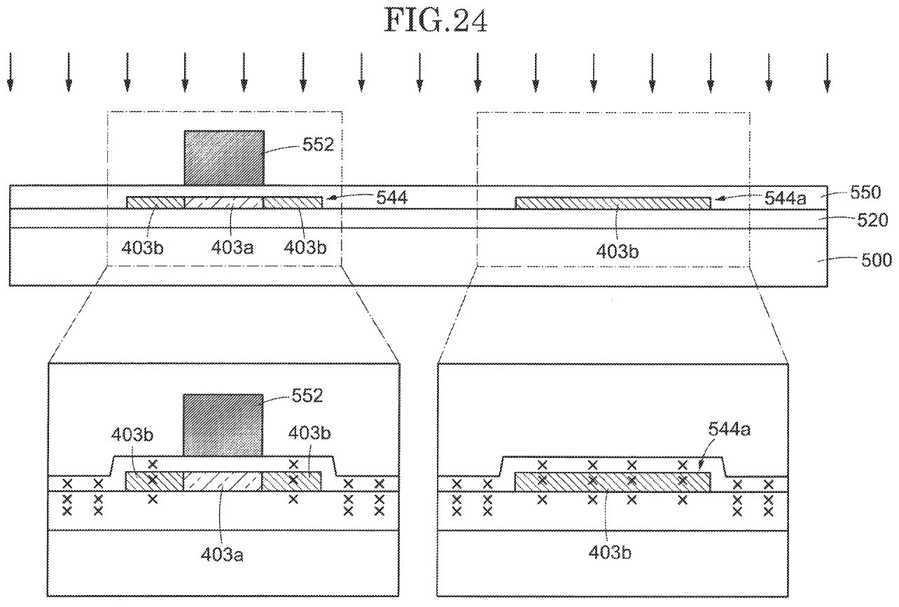

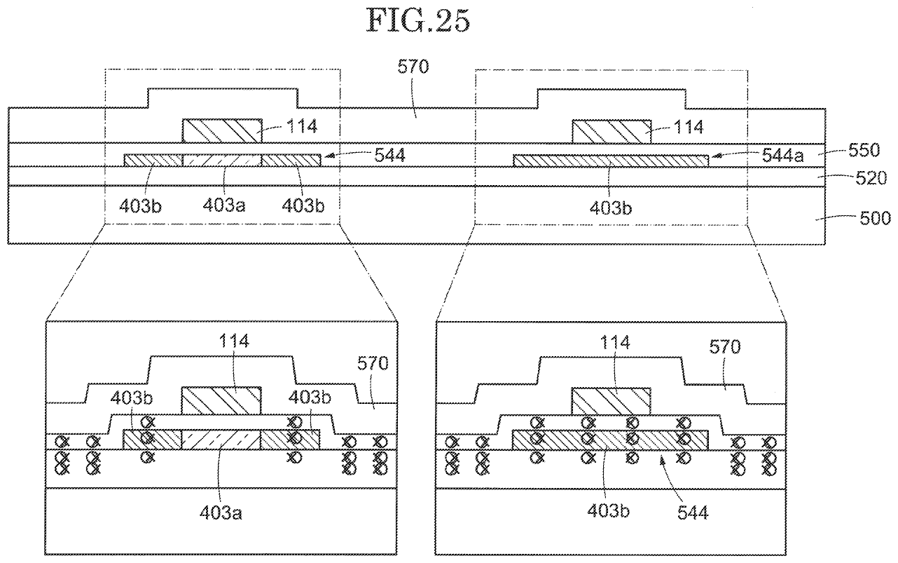

FIG. 23 to FIG. 25 are cross-sectional views showing a method for manufacturing the display device 100 according to an embodiment of the present invention. A stacked structure on the left corresponds to the stacked structure included in the select transistor 201, and a stacked structure on the right corresponds to the stacked structure included in the intersection portion of the scanning signal line 114 and the video signal line 116, in FIG. 23 to FIG. 25. FIG. 24 and FIG. 25 also show enlarged views of each stacked structure for convenience of explanation.

First, the process proceeds to the state shown in FIG. 14 according to the sequence diagram shown in FIG. 9 of the first embodiment. The oxide semiconductor layers 544 and 544a are formed above the insulating layer 520 as shown in FIG. 23. The oxide semiconductor layer 544 functions as the active layer of the select transistor 201. The oxide semiconductor layer 544a is composed of the same layer as the oxide semiconductor layer 544, and is the wiring pattern for use as the video signal line 116.

Thereafter, a resist mask 552 is formed above the insulating layer 550 so as to overlap the oxide semiconductor layer 544. The resist mask 552 is arranged so as to be positioned directly above part of the oxide semiconductor layer 544 that is finally desired to function as the channel portion 403a in the present embodiment.

Next, the impurity element is added to part of the oxide semiconductor layer 544 and the entire oxide semiconductor 544a by the ion implantation as shown in FIG. 24. The conditions and the like of the ion implantation are the same as those of the process shown in FIG. 16 described in the first embodiment. The channel portion 403a and the conductive portion 403b are formed in the oxide semiconductor layer 544 in the process of adding the impurity element as described above. In addition, the symbol “x” in the enlarged view of FIG. 24 schematically indicates a defect formed in the film by the ion-implantation process as in the first embodiment.

On the other hand, since the resist mask 552 is not arranged above the oxide semiconductor layer 544a, the impurity element is added to the entire oxide semiconductor layer 544a. Therefore, the oxide semiconductor layer 544a is reduced in resistance in a process in which the impurity elements are added. That is, the entire video signal line 116 is composed of the oxide semiconductor layer having the same configuration (for example, the same resistivity) as the conductive portion 403b in the present embodiment. In addition, since the impurity element is added to the entire oxide semiconductor layer 544a, the insulating layers 520 and 550 around the oxide semiconductor layer 544a also contain the impurity element.

Next, the scanning signal line 114 is formed so as to overlap the oxide semiconductor layers 544 and 544a as shown in FIG. 25. The scanning signal line 114 that overlaps the oxide semiconductor layer 544 is arranged in accordance with the channel portion 403a. That is, a width of the scanning signal line 114 in a channel length direction is set to coincide with a width of the channel portion 403a or be slightly wider than the width of the channel portion 403a. Arranging the scanning signal line 114 in this manner makes it possible to function the scanning signal line 114 overlapping the oxide semiconductor layer 544 as the gate electrode of the semiconductor device 10.

The insulating layer 570 is then formed above the scanning signal line 114. A silicon nitride layer is formed as the insulating layer 570 as described above in the present embodiment. Although hydrogen diffuses via the insulating layers 520 and 550 in the process of forming the insulating layer 570 as in the first embodiment, the diffused hydrogen is trapped around the oxide semiconductor layer 544 because a large number of defects is formed in the insulating layers 520 and 550. Therefore, most of the hydrogen diffused around the oxide semiconductor layer 544 does not reach the channel portion 403a, and the reduction in resistance due to the hydrogenation of the channel portion 403a does not occur.

The resist mask 552 is used when the channel portion 403a and the conductive portion 403b are formed in the oxide semiconductor layer 544 to be the active layer of the select transistor 201 as described above in the present embodiment. At that time, since the resist mask 552 is not arranged above the oxide semiconductor layer 544a which is the wiring pattern, the entire oxide semiconductor layer 544a can be reduced in resistance by the ion-implantation process.

Therefore, it can be said that each layer in the region (that is, the region where defects exist) that does not overlap the scanning signal line 114 among the stacked structure composed of the insulating layer 520, the oxide semiconductor layer 544, and the insulating layer 550 contains the impurity element, and each layer in the region that overlaps the scanning signal line 114 does not contain the impurity element, as shown in FIG. 25. In addition, it can be said that the stacked structure composed of the insulating layer 520, the oxide semiconductor layer 544a, and the insulating layer 550 contains the impurity element in each of the layers in the region overlapping and not overlapping the scanning signal line 114.

### Third Embodiment

An example in which the part of the video signal line 116 that intersects the scanning signal line 114 is reduced in resistance in a method that is different from that of the first embodiment will be described in the present embodiment. In the following description, the same components as those of the first embodiment will be described with reference to the same reference signs in the drawings, and the description will be omitted, focusing on differences from the first embodiment.

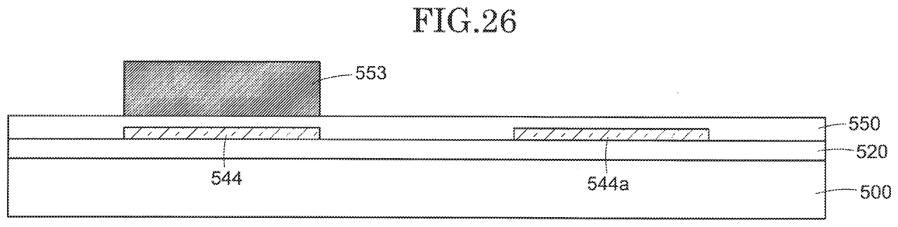

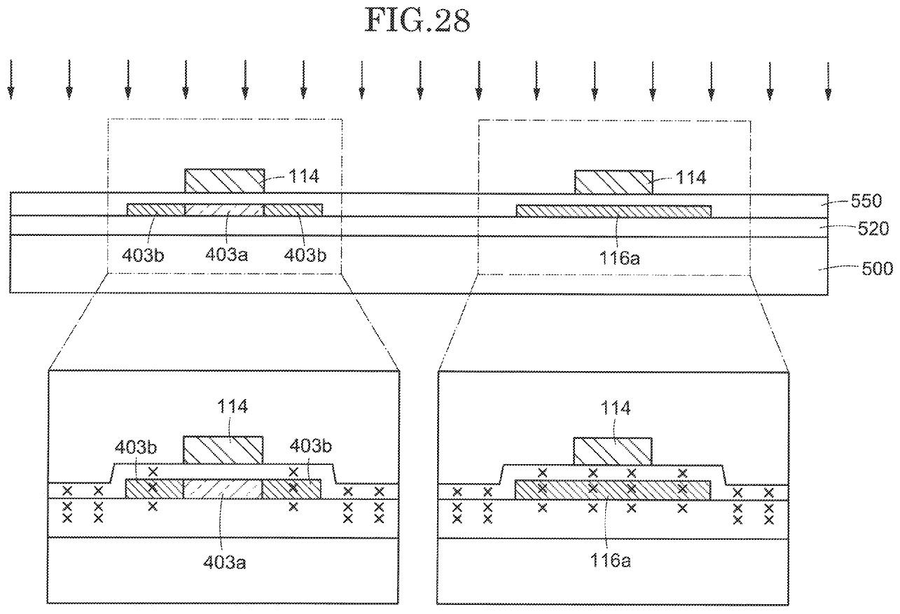

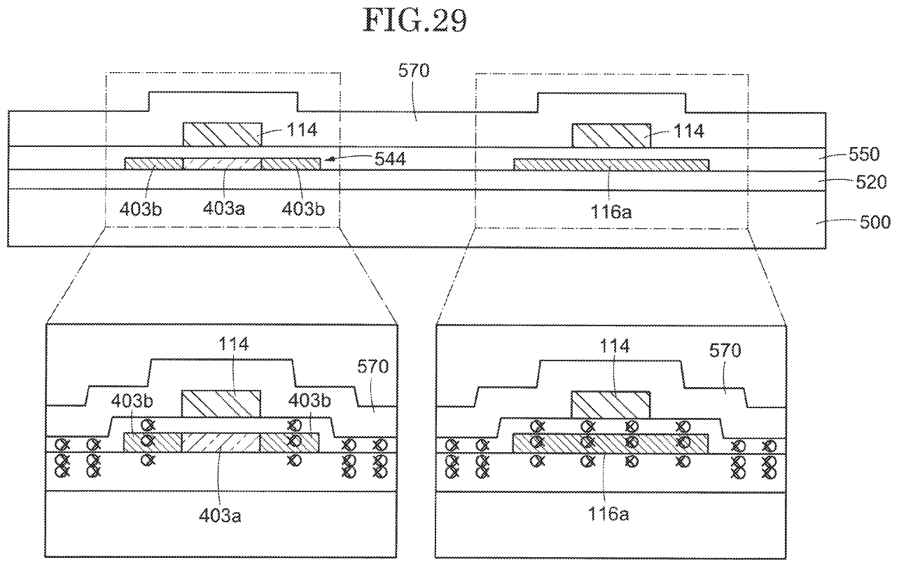

FIG. 26 to FIG. 29 are cross-sectional views showing a method for manufacturing the display device 100 according to an embodiment of the present invention. A stacked structure on the left corresponds to the stacked structure included in the select transistor 201, and a stacked structure on the right corresponds to the stacked structure included in the intersection portion of the scanning signal line 114 and the video signal line 116, in FIG. 26 to FIG. 29. FIG. 28 to FIG. 29 also show enlarged views of each stacked structure for convenience of explanation.

First, the process proceeds to the state shown in FIG. 14 according to the sequence diagram shown in FIG. 9 of the first embodiment. The oxide semiconductor layers 544 and 544a are formed above the insulating layer 520 as shown in FIG. 26. The oxide semiconductor layer 544 functions as the active layer of the select transistor 201. The oxide semiconductor layer 544a is composed of the same layer as the oxide semiconductor layer 544, and is the wiring pattern for use as the video signal line 116.

Thereafter, a resist mask 553 is formed above the insulating layer 550 so as to overlap the oxide semiconductor layer 544. The resist mask 553 is arranged so as to cover the entire oxide semiconductor layer 544 in the present embodiment. However, the present invention is not limited to this example, and the resist mask 553 may be arranged so as to cover part of the oxide semiconductor layer 544. However, a width of the resist mask 553 in the channel length direction is set to be larger than a width of a portion that eventually functions as the channel portion 403a (that is, the width of the scanning signal line 114).

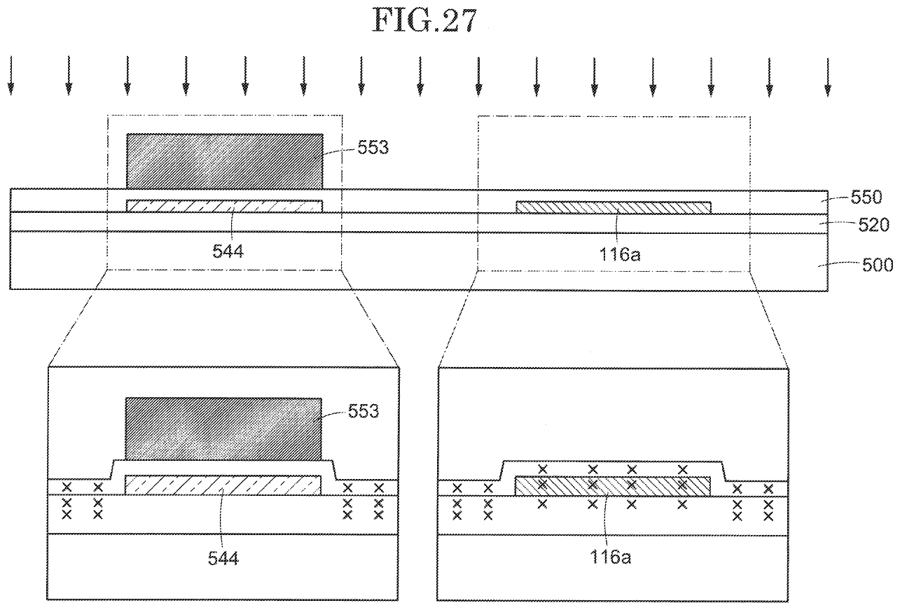

Next, the impurity element is added to the entire oxide semiconductor layer 544a by the ion implantation as shown in FIG. 27. The conditions and the like of the ion implantation are the same as those of the process shown in FIG. 16 described in the first embodiment. The symbol “x” in the enlarged view of FIG. 27 schematically indicates a defect formed in the film by the ion-implantation process as in the first embodiment. Since the oxide semiconductor layer 544 is entirely covered with the resist mask 553 in the process shown in FIG. 27, no impurity elements are added. That is, the oxide semiconductor layer 544 is maintained at a high resistivity.

On the other hand, since the resist mask 552 is not arranged above the oxide semiconductor layer 544a, the impurity element is added to the entire oxide semiconductor layer 544a. Therefore, the oxide semiconductor layer 544a is reduced in resistance in a process in which the impurity elements are added. That is, the entire video signal line 116 is composed of the oxide semiconductor layer having the same configuration (for example, the same resistivity) as the conductive portion 403b in the present embodiment. In addition, since the impurity element is added to the entire oxide semiconductor layer 544a, the insulating layers 520 and 550 around the oxide semiconductor layer 544a also contain the impurity element.

Next, the scanning signal line 114 is formed so as to overlap the oxide semiconductor layers 544 and 544a as shown in FIG. 28, and then the impurity element is added by the ion implantation. In this case, the conditions and the like of the ion implantation may be the same as or different from the process shown in FIG. 27. The channel portion 403a and the conductive portion 403b are formed in the oxide semiconductor layer 544 by the process shown in FIG. 28. Since the impurity element is added to the oxide semiconductor layer 544 using the scanning signal line 114 (gate electrode) as a mask, the channel portion 403a and the conductive portion 403b are formed in self-alignment. Although the impurity element is added to the region in the oxide semiconductor layer 544a that does not overlap the scanning signal line 114 again, an adequate amount of impurity elements has been added during the first ion implantation, and the resistivity of the oxide semiconductor layer 544a is not significantly changed.

Next, the insulating layer 570 is formed above the scanning signal line 114 as shown in FIG. 29. A silicon nitride layer is formed as the insulating layer 570 in the present embodiment. Although hydrogen diffuses via the insulating layers 520 and 550 in the process of forming the insulating layer 570 as in the first embodiment, the diffused hydrogen is trapped around the oxide semiconductor layer 544 because a large number of defects is formed in the insulating layers 520 and 550. Therefore, most of the hydrogen diffused around the oxide semiconductor layer 544 does not reach the channel portion 403a, and the reduction in resistance due to the hydrogenation of the channel portion 403a does not occur.

The impurity element is added to the entire oxide semiconductor layer 544a, which is the wiring pattern, by the ion implantation in advance, so that the entire oxide semiconductor layer 544a is reduced in resistance as described above in the present embodiment. Thereafter, the channel portion 403a and the conductive portion 403b are formed in the oxide semiconductor layer 544 to be the active layer of the select transistor 201 using the scanning signal line 114 as a mask. According to the present embodiment, it is possible to form the active layer of the select transistor 201 in self-alignment while forming the entire oxide semiconductor layer 544a with the conductive portion 403b.

In addition, according to the present embodiment, the distribution of the impurity element in the stacked structure composed of the insulating layer 520, the oxide semiconductor layer 544, and the insulating layer 550 and the distribution of the impurity element in the stacked structure composed of the insulating layer 520, the oxide semiconductor layer 544a, and the insulating layer 550 are the same as those in the second embodiment.

### Fourth Embodiment

An example in which the video signal line 116 overlapping the scanning signal line 114 is reduced in resistance in the stacked structure in which the scanning signal line 114 and the video signal line 116 intersect has been described in the first embodiment to the third embodiment. However, the configuration described in the first embodiment to the third embodiment can be applied to any configuration as long as it is a stacked structure in which a conductive layer composed of the oxide semiconductor and another conductive layer overlap. For example, the configurations described in the first embodiment to the third embodiment can also be applied to the case where a capacitive element is formed.

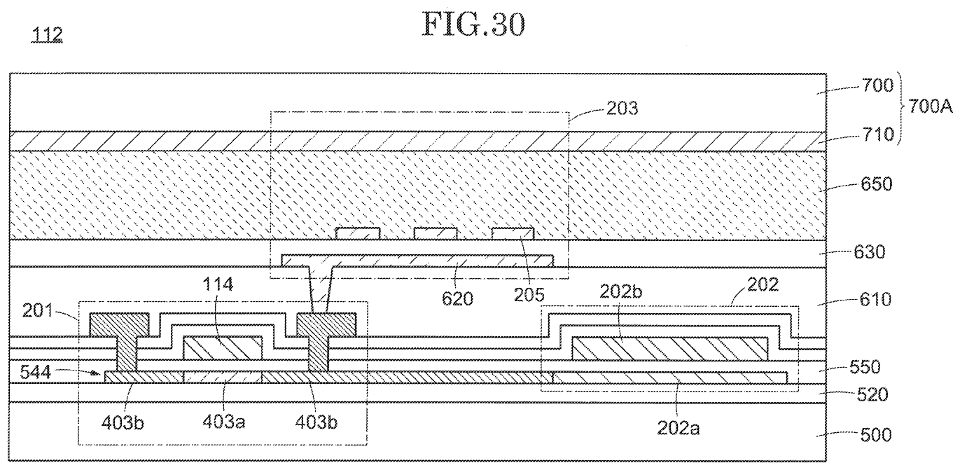

FIG. 30 is a cross-sectional view showing a configuration of the pixel 112 in the display device 100 according to an embodiment of the present invention. Specifically, FIG. 30 shows the select transistor 201 and the capacitive element 202 arranged in the pixel 112. In addition, the same configurations as those in FIG. 4 of the first embodiment are denoted by the same reference signs, and description thereof will be omitted.

For example, a lower electrode 202a of the capacitive element 202 can be formed using the oxide semiconductor layer formed of the same layer as the active layer (the oxide semiconductor layer 544) of the select transistor 201 in the present embodiment. The oxide semiconductor layer reduced in resistance by hydrogenation is used as the lower electrode 202a in the embodiment shown in FIG. 30 as in the first embodiment. For example, the insulating layer 550 can be used as an insulator of the capacitive element 202. For example, an upper electrode 202b of the capacitive element 202 can be formed using a metal layer composed of the same layer as the gate electrode (the scanning signal line 114) of the select transistor 201.

Since the oxide semiconductor layer located directly below the upper electrode 202b of the capacitive element 202 can be sufficiently reduced in resistance in the present embodiment, the oxide semiconductor layer can be used as the lower electrode 202a of the capacitive element 202. In this case, since the conductive portion 403b connecting the select transistor 201 and the capacitive element 202 is transparent to visible light, there is no need to worry about a decrease in the aperture ratio regardless of the arrangement of the conductive portion 403b in the pixel 112.

### Fifth Embodiment

A semiconductor device 10a having a configuration that is different from the configuration of the semiconductor device 10 described in the first embodiment will be described in the present embodiment.

The configuration of the semiconductor device 10a is similar to that of the semiconductor device 10 of the first embodiment, but is different from that of the semiconductor device 10 of the first embodiment in that a metal oxide layer 530 is arranged between the insulating layer 520 and the oxide semiconductor layer 544 serving as a base. The same configuration as in the first embodiment will be omitted, and differences from the first embodiment will be mainly described in the following description.

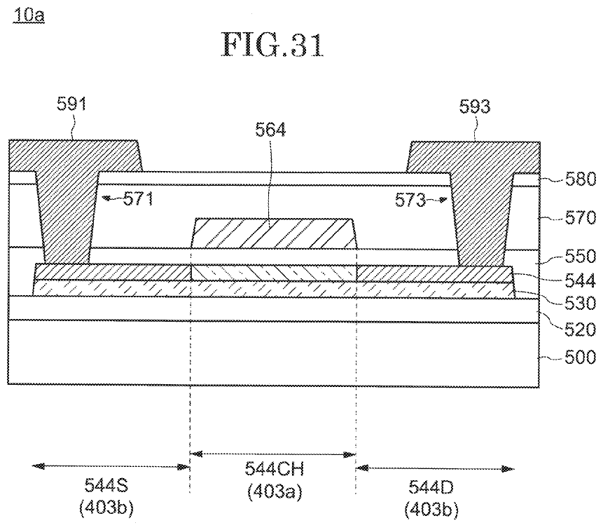

FIG. 31 is a cross-sectional view showing a configuration of the semiconductor device 10a used in the display device 100 according to an embodiment of the present invention. The semiconductor device 10a includes the insulating layer 520, the metal oxide layer 530, the oxide semiconductor layer 544, the insulating layer 550, the gate electrode 564, the insulating layer 570, the insulating layer 580, the source electrode 591, and the drain electrode 593, as shown in FIG. 31.

The metal oxide layer 530 is arranged above the insulating layer 520. The metal oxide layer 530 is in contact with the insulating layer 520. The oxide semiconductor layer 544 is arranged above the metal oxide layer 530. The lower surface of the oxide semiconductor layer 544 is in contact with the metal oxide layer 530. An end portion of the metal oxide layer 530 and an end portion of the oxide semiconductor layer 544 substantially coincide with each other in the present embodiment.

The metal oxide layer 530 is a layer containing a metal oxide containing aluminum as a main component in the same manner as the metal oxide layer 555 (see FIG. 13), and has a function as a gas barrier film for shielding a gas such as oxygen or hydrogen. Although material similar to that of the metal oxide layer 555 can be used as the metal oxide layer 530, a different material may be used.

Although a planar shape of the semiconductor device 10a is the same as that of FIG. 6, and the description is omitted, a planar pattern of the metal oxide layer 530 in a plan view is substantially the same as a planar pattern of the oxide semiconductor layer 544. The lower surface of the oxide semiconductor layer 544 is covered with the metal oxide layer 530 with reference to FIG. 31. In particular, all of the lower surface of the oxide semiconductor layer 544 is covered with the metal oxide layer 530 in the present embodiment.

When the proportion of indium in the oxide semiconductor layer 544 is 50% or more, the semiconductor device 10a with high mobility can be realized. On the other hand, in such the oxide semiconductor layer 544, oxygen contained in the oxide semiconductor layer 544 is easily reduced, and oxygen defects are easily formed in the oxide semiconductor layer 544.

Hydrogen is released from a layer (for example, the insulating layer 520) arranged closer to the substrate 500 than the oxide semiconductor layer 544 during a heat treatment step of the manufacturing process in a top-gate structure, such as the semiconductor device 10a. When hydrogen released from the lower layer reaches the oxide semiconductor layer 544, oxygen defects may occur in the oxide semiconductor layer 544. The occurrence of oxygen defects is more significant as the pattern size of the oxide semiconductor layer 544 increases. In order to suppress such the occurrence of oxygen defects, it is preferable to suppress hydrogen from reaching the lower surface of the oxide semiconductor layer 544.

In addition, the upper surface of the oxide semiconductor layer 544 is affected by a process (for example, a patterning process or an etching process) after the oxide semiconductor layer 544 is formed. On the other hand, the lower surface of the oxide semiconductor layer 544 is not affected as described above. Therefore, the oxygen defects formed on the upper surface of the oxide semiconductor layer 544 are larger than the oxygen defects formed on the lower surface of the oxide semiconductor layer 544. That is, the oxygen defects in the oxide semiconductor layer 544 are not present in a uniform distribution in the thickness direction of the oxide semiconductor layer 544, but in a non-uniform distribution in the thickness direction of the oxide semiconductor layer 544. Specifically, the oxide semiconductor layer 544 has less oxygen defects on the lower surface side of the oxide semiconductor layer 544 and more oxygen defects on the upper surface side of the oxide semiconductor layer 544.

When the amount of oxygen required to repair the oxygen defects formed on the upper surface side of the oxide semiconductor layer 544 is uniformly supplied to the oxide semiconductor layer 544 in which the oxygen defects are distributed as described above, oxygen is excessively supplied to the lower surface side of the oxide semiconductor layer 544. As a result, a defect level different from the oxygen defect may be formed on the lower surface side due to the excessive oxygen, and there is a possibility that a phenomenon such as characteristic variation in a reliability test or a decrease in field-effect mobility may occur. Therefore, in order to suppress such a phenomenon, it is desirable to supply oxygen to the upper surface side of the oxide semiconductor layer 544 while suppressing oxygen supply to the lower surface side of the oxide semiconductor layer 544.

Even if the initial characteristics of the semiconductor device are improved by the oxygen supply treatment to the oxide semiconductor layer, there is a possibility that the characteristic variation due to the reliability test may occur in the configuration and the manufacturing method of the first embodiment as described above. That is, it can be said that there is a trade-off relationship between the initial characteristics and the reliability test. However, according to the present embodiment, arranging the metal oxide layer 530 on the lower surface of the oxide semiconductor layer 544 makes it possible to obtain good initial characteristics and the reliability test of the semiconductor device 10a.

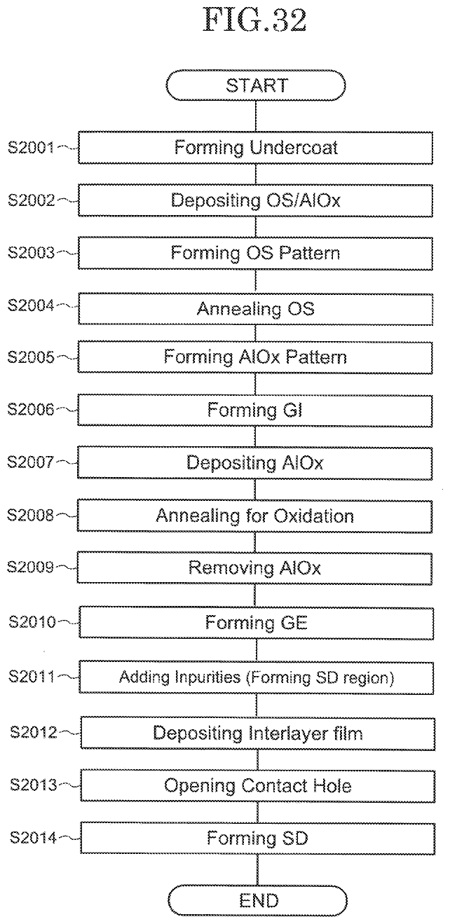

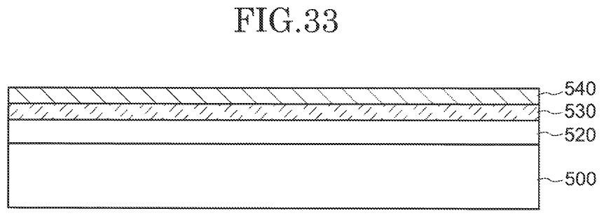

A method for manufacturing the semiconductor device 10a used in the display device 100 according to an embodiment of the present invention will be described with reference to FIG. 32 to FIG. 35. FIG. 32 is a sequence diagram showing a method for manufacturing the semiconductor device 10a used in the display device 100 according to an embodiment of the present invention. FIG. 33 to FIG. 35 are cross-sectional views showing a method for manufacturing the semiconductor device 10a used in the display device 100 according to an embodiment of the present invention.

The insulating layer 520 is formed above the substrate 500 (step S2001) as shown in FIG. 32. The step S2001 may refer to the explanation of the step S1001 shown in FIG. 9 and FIG. 10. Silicon nitride and silicon oxide are used as the insulating layer 520 in the present embodiment. Silicon oxide is preferred for reducing the oxygen defects in the oxide semiconductor layer 544 because it releases oxygen by heat treatment.

The metal oxide layer 530 and the oxide semiconductor layer 540 are formed above the insulating layer 520 (step S2002) as shown in FIG. 32 and FIG. 33. The metal oxide layer 530 and the oxide semiconductor layer 540 are deposited by the sputtering method or the atomic layer deposition method (ALD).

The material of the metal oxide layer 530 may refer to the description of the material of the metal oxide layer 555 shown in FIG. 13. For example, a thickness of the metal oxide layer 530 is 1 nm or more and 100 nm or less, 1 nm or more and 50 nm or less, 1 nm or more and 30 nm or less, or 1 nm or more and 10 nm or less. Aluminum oxide is used as the metal oxide layer 530 in the present embodiment. Aluminum oxide has a high barrier property against gas. The aluminum oxide used as the metal oxide layer 530 blocks hydrogen and oxygen released from the insulating layer 520 and suppresses the released hydrogen and oxygen from reaching the oxide semiconductor layer 540 in the present embodiment.

For example, the thickness of the oxide semiconductor layer 540 is 10 nm or more and 100 nm or less, 15 nm or more and 70 nm or less, or 20 nm or more and 40 nm or less. An oxide containing indium (In) and gallium (Ga) is used as the oxide semiconductor layer 540 in the present embodiment. The oxide semiconductor layer 540 before the OS annealing performed in step S2004 described below is amorphous.

In the case where the oxide semiconductor layer 540 is crystallized by the OS annealing described later, the oxide semiconductor layer 540 after the deposition and before the OS annealing is preferably amorphous (a state in which the oxide semiconductor has few crystalline component). The deposition method in which the oxide semiconductor layer 540 after the deposition is amorphous may refer to the explanation of the step S1002 shown in FIG. 9.

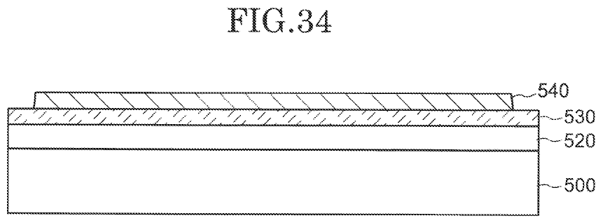

Next, a pattern of the oxide semiconductor layer 540 is formed as shown in FIG. 32 and FIG. 34 (step S2003). Although not shown, a resist mask is formed above the oxide semiconductor layer 540, and the oxide semiconductor layer 540 is etched using the resist mask. Etching of the oxide semiconductor layer 540 may be performed by either wet etching or dry etching. The wet etching can be performed using an acidic etchant. For example, oxalic acid or hydrofluoric acid can be used as the acidic etchant.

Next, the heat treatment (OS annealing) is performed on the oxide semiconductor layer 540 (step S2004) after the pattern of the oxide semiconductor layer 540 is formed, as shown in FIG. 32. The oxide semiconductor layer 540 is crystallized by the OS annealing in the present embodiment. In addition, the crystallized oxide semiconductor layer is referred to as the oxide semiconductor layer 544.

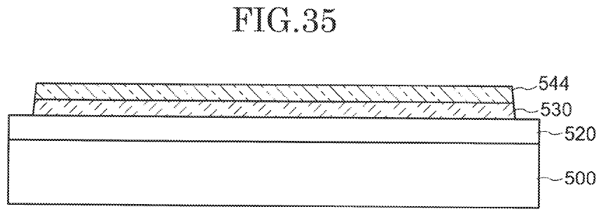

Next, a pattern of the metal oxide layer 530 is formed (step S2005) as shown in FIG. 32 and FIG. 35. The metal oxide layer 530 is etched using the crystallized oxide semiconductor layer 544 as a mask. Etching of the metal oxide layer 530 may be performed by either wet etching or dry etching. For example, dilute hydrofluoric acid (DHF) is used as the etchant for wet etching. The crystallized oxide semiconductor layer 544 has etching resistance against dilute hydrofluoric acid as compared with the amorphous oxide semiconductor layer 540. Therefore, the metal oxide layer 530 can be etched in a self-aligned manner using the oxide semiconductor layer 544 as a mask. As a result, a photolithography step can be omitted.

Since the steps shown in the step S2006 to the step S2014 shown in FIG. 32 are the same as the step S1005 to the step S1013 shown in FIG. 9, the following explanation will be omitted. The semiconductor device 10a shown in FIG. 31 can be formed by passing through the step S2006 to the step S2014.

Electric properties (specifically, field-effect mobility) having a mobility of 50 cm²/Vs or more, 55 cm²/Vs or more, or 60 cm²/Vs or more can be obtained in a range where the channel length L of the channel region 544CH is 2 μm or more and 4 μm or less and the channel width of the channel region 544CH is 2 μm or more and 25 μm or less, in the semiconductor device 10a manufactured by the above-described manufacturing method. The definition of the field-effect mobility in the present embodiment is the same as that in the first embodiment.

### Sixth Embodiment

A semiconductor device manufactured by a method that is different from the fifth embodiment will be described in the present embodiment. Since the appearance of the structure of the semiconductor device of the present embodiment is the same as that of the semiconductor device 10a described in the second embodiment, it will be described as the semiconductor device 10a in the following description. The present embodiment will be described focusing on differences from the fifth embodiment.

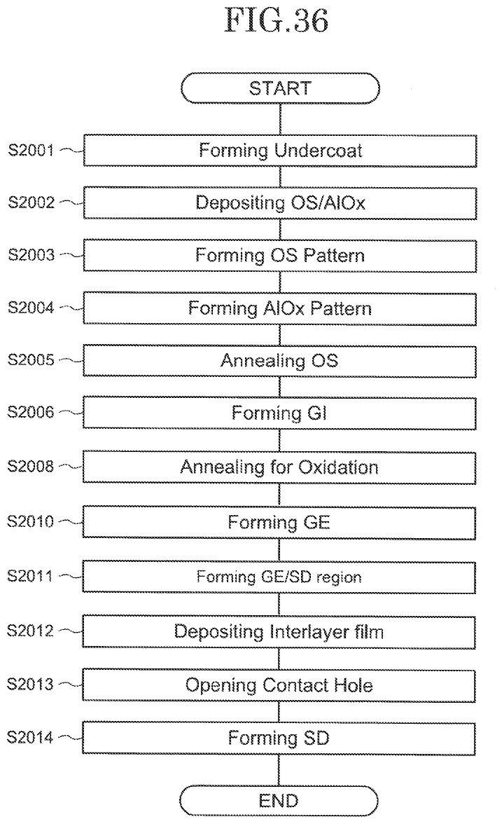

FIG. 36 is a sequence diagram showing a method for manufacturing the semiconductor device 10a used in the display device 100 according to an embodiment of the present invention. Two steps of step S2007 and step S2009 shown in FIG. 32 are omitted in the present embodiment, as shown in FIG. 36. That is, the insulating layer 550 is formed, and then the oxidation annealing (step S2008) is performed in that state, in the present embodiment. The oxygen released from the insulating layer 550 is supplied to the oxide semiconductor layer 540 by oxidation annealing, and the oxygen defects contained in the oxide semiconductor layer 540 are repaired. Since the role of the metal oxide layer 530 in this case is the same as that of the fifth embodiment, the description thereof will be omitted.

Electric properties (specifically, field-effect mobility) having a mobility of 30 cm²/Vs or more, 35 cm²/Vs or more, or 40 cm²/Vs or more can be obtained in a range where the channel length L of the channel region 544CH is 2 μm or more and 4 μm or less and the channel width of the channel region 544CH is 2 μm or more and 25 μm or less, in the semiconductor device 10a manufactured by the manufacturing method of the present embodiment. The definition of the field-effect mobility in the present embodiment is the same as that in the first embodiment.

### Seventh Embodiment

A semiconductor device manufactured in a method that is different from that of the first embodiment will be described in the present embodiment. Since the appearance of the structure of the semiconductor device of the present embodiment is the same as that of the semiconductor device 10 described in the first embodiment, it will be described as the semiconductor device 10 in the following description. The present embodiment will be described focusing on differences from the first embodiment.

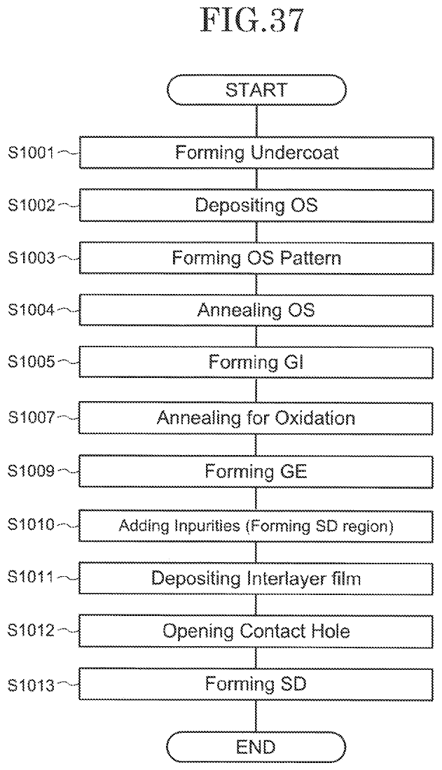

FIG. 37 is a sequence diagram showing a method for manufacturing the semiconductor device 10 used in the display device 100 according to an embodiment of the present invention. Two steps of step S1006 and step S1008 shown in FIG. 9 are omitted in the present embodiment as shown in FIG. 37. That is, the insulating layer 550 is formed, and then the oxidation annealing (step S1007) is performed in that state in the present embodiment. The oxygen released from the insulating layer 550 is supplied to the oxide semiconductor layer 544 by oxidation annealing, and the oxygen defects contained in the oxide semiconductor layer 544 are repaired.

### Eighth Embodiment

Although it has been described exemplifying the liquid crystal display device as the display device 100 in the first embodiment, an example in which the present invention is applied to an organic EL display device will be described in the present embodiment. Configurations different from those of the first embodiment will be described in the present embodiment, and the same configurations will be illustrated using the same reference signs, and description thereof will be omitted.

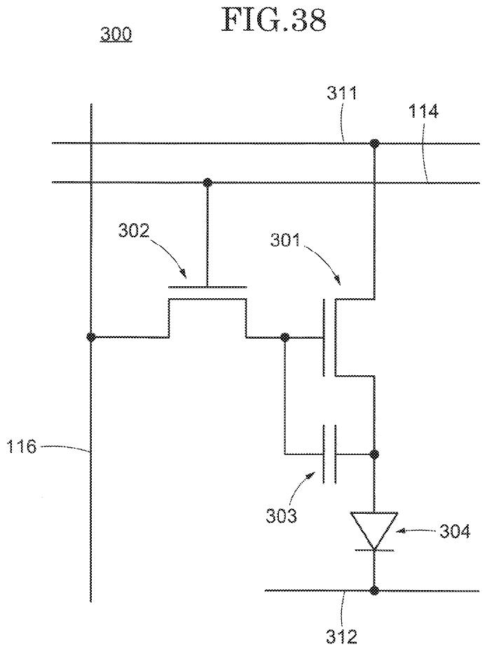

FIG. 38 is a diagram showing a configuration of a pixel circuit 300 in the display device according to an embodiment of the present invention. The pixel circuit 300 is a circuit for controlling light emission of each pixel 112 (see FIG. 1). Although a basic configuration using two semiconductor devices is exemplified for convenience of explanation in the example shown in FIG. 38, the present invention is not limited to this example.

The pixel circuit 300 of the present embodiment includes a drive transistor 301, a select transistor 302, a storage capacitor 303, and a light-emitting element 304, as shown in FIG. 38. The drive transistor 301 and the select transistor 302 are formed of a semiconductor device (specifically, a thin film transistor) using the oxide semiconductor layer.

A source of the drive transistor 301 is connected to an anode power line 311, and a drain of the drive transistor 301 is connected to one end (anode) of the light-emitting element 304. The other end (cathode) of the light-emitting element 304 is connected to a common wiring 312. That is, the common wiring 312 functions as a cathode power line during the display period. A power-supply voltage higher than the common wiring 312 is applied to the anode power line 311.

A gate of the select transistor 302 is connected to the scanning signal line 114 and a source of the select transistor 302 is connected to the video signal line 116. A drain of the select transistor 302 is connected to a gate of the drive transistor 301. In addition, the source and drain of the select transistor 302 may be switched depending on the relationship between the voltage applied to the video signal line 116 and the voltage stored in the storage capacitor 303.

The storage capacitor 303 is connected to the gate and drain of the drive transistor 301 and the drain of the select transistor 302. A gradation signal determining the emission intensity of the light-emitting element 304 is supplied to the video signal line 116. A scanning signal for selecting a pixel to which the gradation signal is written is supplied to the scanning signal line 114.

The gradation signal (gradation voltage) input from the video signal line 116 via the select transistor 302 is held in the storage capacitor 303 in the above-described pixel circuit 300. A current corresponding to the voltage held in the storage capacitor 303 flows from the anode power line 311 toward the light-emitting element 304 via the drive transistor 301, in the display period (light-emitting period). The light-emitting element 304 is an organic EL element in the present embodiment. The light-emitting element 304 emits light with a brightness corresponding to the amount of current flowing between the anode electrode and the cathode electrode.

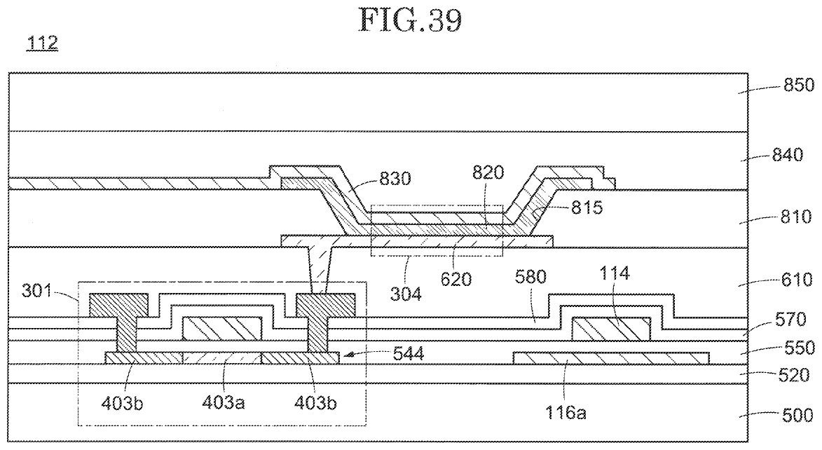

FIG. 39 is a cross-sectional view showing a structure of the pixel 112 in the display device according to an embodiment of the present invention. The drive transistor 301 is arranged above the substrate 500 on which the insulating layer 520 is arranged, as shown in FIG. 39. The drive transistor 301 of the present embodiment includes the oxide semiconductor layer 544 having a polycrystalline structure. Since the basic structure of the drive transistor 301 is the same as the structure of the select transistor 201 of the first embodiment, detailed explanation thereof will be omitted.

The video signal line 116 (specifically, the intersection portion 116a) composed of the same layer as the oxide semiconductor layer 544 of the drive transistor 301 is arranged above the insulating layer 520. The video signal line 116 of the present embodiment is a wiring that is reduced in resistance by hydrogenating the oxide semiconductor layer in the same process as in the first embodiment.

The pixel electrode 620 that functions as an anode electrode of the light-emitting element 304 is arranged in the drive transistor 301. The pixel electrode 620 has a structure in which the transparent conductive film, such as ITO, and the metal layer, such as silver, are stacked, in the present embodiment. An end portion of the pixel electrode 620 is covered with a resin layer 810 called a bank or rib. An opening 815 in the resin layer 810 exposes part of the surface of the pixel electrode 620. The outer shape of the surface of the pixel electrode 620 exposed by the opening 815 defines a light-emitting region of the light-emitting element 304.

A light-emitting layer 820 and a common electrode 830 are arranged inside the opening 815. The common electrode 830 functions as a cathode of the light-emitting element 304 and is arranged across the plurality of pixels 112. On the other hand, the pixel electrode 620 and the light-emitting layer 820 are arranged separately for each pixel 112. Different materials are used for the light-emitting layer 820 depending on the display color of the pixel. Although only the light-emitting layer 820 is illustrated in FIG. 39, a functional layer such as a hole injection layer, a hole transport layer, an electron injection layer, and an electron transport layer may be arranged in addition to the light-emitting layer 820.

A sealing layer 840 is arranged above the light-emitting element 304. The sealing layer 840 may be composed of a resin material, or may be composed by combining a resin material and an inorganic material. The sealing layer 840 of the present embodiment has a three-layer structure in which a resin layer is sandwiched between silicon nitride layers. A protective substrate 850 is arranged above the sealing layer 840. A light transmittance substrate such as a glass substrate can be used as the protective substrate 850.

Each of the embodiments described above as an embodiment of the present invention can be appropriately combined and implemented as long as no contradiction is caused. In addition, the addition, deletion, or design change of components as appropriate by those skilled in the art based on each embodiment are also included in the scope of the present invention as long as they are provided with the gist of the present invention.

Further, it is understood that, even if the effect is different from those provided by each of the above-described embodiments, the effect obvious from the description in the specification or easily predicted by persons ordinarily skilled in the art is apparently derived from the present invention.

What is claimed is:

1. An electronic device comprising:
a first stacked structure including a first oxide semiconductor layer having a polycrystalline structure, a first insulating layer on the first oxide semiconductor layer, and a first conductive layer overlapping the first oxide semiconductor layer via the first insulating layer; and
a second stacked structure including a second oxide semiconductor layer composed of the same layer as the first oxide semiconductor layer, the first insulating layer on the second oxide semiconductor layer, and a second conductive layer overlapping the second oxide semiconductor layer via the first insulating layer and composed of the same layer as the first conductive layer, wherein
the first oxide semiconductor layer includes a first portion overlapping the first conductive layer and a second portion not overlapping the first conductive layer,
the second oxide semiconductor layer includes a third portion overlapping the second conductive layer and a fourth portion not overlapping the second conductive layer,
the second portion contains an impurity element, and
the first portion, the third portion and the fourth portion do not contain the impurity element.

2. The electronic device according to claim 1, wherein
in a plan view, the first insulating layer located within a predetermined range from an edge of the first oxide semiconductor layer toward the outside contains the impurity element, and
in a plan view, the first insulating layer located within the predetermined range from the edge of the second oxide semiconductor layer toward the outside does not contain the impurity element.

3. The electronic device according to claim 1, wherein
the resistivity of the second portion is lower than that of the first portion, and
the resistivity of the third portion is lower than that of the first portion.

4. The electronic device according to claim 3, wherein
the resistivity of the third portion is the same as that of the fourth portion.

5. The electronic device according to claim 1, wherein
the first insulating layer includes a fifth portion overlapping the first conductive layer, a sixth portion not overlapping the first conductive layer but overlapping the first oxide semiconductor layer, and a seventh portion overlapping the second oxide semiconductor layer,
the sixth portion contains the impurity element, and
the fifth portion and the seventh portion do not contain the impurity element.

6. The electronic device according to claim 1, wherein
the first oxide semiconductor layer and the second oxide semiconductor layer are provided on the second insulating layer,
the eighth portion in the second insulating layer overlapping the first conductive layer and the first oxide semiconductor layer contains the impurity element,
the ninth portion in the second insulating layer not overlapping the first conductive layer but overlapping the first oxide semiconductor layer contains the impurity element, and
the tenth portion in the second insulating layer overlapping the second oxide semiconductor layer does not contain the impurity element.

7. The electronic device according to claim 1, wherein
the crystal structure of the second portion is the same as that of the first portion.

8. The electronic device according to claim 1, wherein
in a predetermined crystalline orientation, a face spacing d of the crystalline structure of the second portion is approximately the same as a face spacing d of the crystalline structure of the first portion.

9. The electronic device according to claim 1, wherein
the crystalline structure of the first portion and the second portion are cubic.

10. The electronic device according to claim 1, wherein
the first oxide semiconductor and the second oxide semiconductor contain at least two or more metallic elements including indium, and
a ratio of indium to the at least two or more metallic elements is 50% or more.

11. The electronic device according to claim 1, wherein
the first stacked structure includes a thin-film transistor, and
the second stacked structure includes a wiring intersection or a capacitive element.

12. An electronic device comprising:
a first stacked structure including a first oxide semiconductor layer having a polycrystalline structure, a first insulating layer on the first oxide semiconductor layer, and a first conductive layer overlapping the first oxide semiconductor layer via the first insulating layer; and
a second stacked structure including a second oxide semiconductor layer composed of the same layer as the first oxide semiconductor layer, the first insulating layer on the second oxide semiconductor layer, and a second conductive layer overlapping the second oxide semiconductor layer via the first insulating layer and composed of the same layer as the first conductive layer, wherein
the first oxide semiconductor layer includes a first portion overlapping the first conductive layer and a second portion not overlapping the first conductive layer,
the second oxide semiconductor layer includes a third portion overlapping the second conductive layer and a fourth portion not overlapping the second conductive layer,
the second portion, the third portion and the fourth portion contain an impurity element, and
the first portion does not contain the impurity element.

13. The electronic device according to claim 12, wherein
the resistivity of the second portion is lower than that of the first portion, and
the resistivity of the third portion and the fourth portion are the same as that of the second portion.

14. The electronic device according to claim 12, wherein
the first insulating layer includes a fifth portion overlapping the first conductive layer, a sixth portion not overlapping the first conductive layer but overlapping the first oxide semiconductor layer, and a seventh portion overlapping the second oxide semiconductor layer,
the sixth portion and the seventh portion contain the impurity element, and
the fifth portion does not contain the impurity element.

15. The electronic device according to claim 12, wherein
the first oxide semiconductor layer and the second oxide semiconductor layer are provided on the second insulating layer,
the eighth portion in the second insulating layer overlapping the first conductive layer and the first oxide semiconductor layer does not contain the impurity element,
the ninth portion in the second insulating layer not overlapping the first conductive layer but overlapping the first oxide semiconductor layer contains the impurity element, and
the tenth portion in the second insulating layer overlapping the second oxide semiconductor layer contains the impurity element.

16. The electronic device according to claim 12, wherein
the crystal structure of the second portion is the same as that of the first portion.

17. The electronic device according to claim 12, wherein
in a predetermined crystalline orientation, a face spacing d of the crystalline structure of the second portion is approximately the same as a face spacing d of the crystalline structure of the first portion.

18. The electronic device according to claim 12, wherein
the crystalline structure of the first portion and the second portion are cubic.

19. The electronic device according to claim 12, wherein
the first oxide semiconductor and the second oxide semiconductor contain at least two or more metallic elements including indium, and
a ratio of indium to the at least two or more metallic elements is 50% or more.

20. The electronic device according to claim 12, wherein
the first stacked structure includes a thin-film transistor, and
the second stacked structure includes a wiring intersection or a capacitive element.
